(19) United States
(12) Patent Application Publication
(10) Pub. No.: US 2025/0275363 A1
(43) Pub. Date: Aug. 28, 2025

(54) DISPLAY DEVICE

(71) Applicant: LG Display Co., Ltd., Seoul (KR)

(72) Inventors: YunHo KOOK, Goyang-si (KR); Jonghan PARK, Seoul (KR); Seonwoo AHN, Seoul (KR); Jihyang YOON, Ulsan (KR); Chaeeun SONG, Seoul (KR); SeungHee NAM, Paju-si (KR)

(73) Assignee: LG Display Co., Ltd., Seoul (KR)

(21) Appl. No.: 18/978,765

(22) Filed: Dec. 12, 2024

(30) Foreign Application Priority Data
Feb. 26, 2024 (KR) 10-2024-0027613

(51) Int. Cl. H10K 59/121; H10K 59/122; H10K 59/35; H10K 59/80

(52) U.S. Cl. CPC H10K 59/1213; H10K 59/122; H10K 59/353; H10K 59/873

(57) ABSTRACT

A display device may include: a substrate; a display area having subpixels; an optical area in the display area; a transistor in each subpixel; a first planarization layer disposed on the transistor; a second planarization layer disposed on the first planarization layer; a third planarization layer disposed on the second planarization layer and exposing a top surface of the second planarization layer; an anode disposed in each subpixel and covering the top surface of the second planarization layer and a part of the third planarization layer; a dam structure disposed on the substrate and including a first layer formed of the same layer as the second planarization layer, and a second layer formed of the same layer as the third planarization layer; and first patterns disposed along the dam structure, each first pattern having a planar shape including a curved line.

### CROSS-REFERENCE TO RELATED APPLICATIONS

This application claims the benefit of and priority to Korean Patent Application No. 10-2024-0027613 filed on Feb. 26, 2024, the entire contents of which are incorporated herein by reference for all purposes.

### BACKGROUND

### 1. Technical Field

The present disclosure relates to a display device, and more particularly to, for example, without limitation, a display device with improved light extraction efficiency and a reduced bezel.

### 2. Description of the Related Art

Recently, display devices, which visually display electrical information signals, are being rapidly developed in accordance with the full-fledged entry into the information era. Various studies are being continuously conducted to develop a variety of display devices which are thin and lightweight, consume low power, and have improved performance.

Among the various display devices, a light-emitting display device refers to a display device that autonomously emits light. Unlike a liquid crystal display device, the light-emitting display device does not require a separate light source and thus may be manufactured as a lightweight, thin display device. In addition, the light-emitting display device is advantageous in terms of power consumption because the light-emitting display device operates at a low voltage. Further, the light-emitting display device is expected to be adopted in various fields because the light-emitting display device is also excellent in implementation of colors, response speeds, viewing angles, and contrast ratios (CRs).

The description of the related art should not be assumed to be prior art merely because it is mentioned in or associated with this section. The description of the related art includes information that describes one or more aspects of the subject technology, and the description in this section does not limit the invention.

### SUMMARY

An aspect to be achieved by the present disclosure is to provide a high-efficiency, low-power consumption display device capable of improving luminous efficiency of a light-emitting element by using an anode with a side mirror structure.

Another aspect to be achieved by the present disclosure is to provide a display device capable of stably controlling a flow of a second encapsulation layer.

Still another aspect to be achieved by the present disclosure is to provide a display device capable of minimizing an optical area, which is disposed in a display area, and a size of a bezel of a non-display area.

Aspects of the present disclosure are not limited to the above-mentioned aspects, and other aspects, which are not mentioned above, can be clearly understood by those skilled in the art from the present disclosure.

A display device according to one or more example embodiments of the present disclosure may include: a substrate; a display area in which a plurality of subpixels is disposed; an optical area; a non-display area outside the display area; a transistor disposed in each of the plurality of subpixels on the substrate; a first planarization layer disposed on the transistor; a second planarization layer disposed on the first planarization layer; a third planarization layer disposed on the second planarization layer and configured to expose parts of a top surface of the second planarization layer; an anode disposed in each of the plurality of subpixels and configured to cover a part of the top surface of the second planarization layer and a part of the third planarization layer; a dam structure disposed on the substrate and including a first layer formed of a same layer as the second planarization layer, and a second layer formed of a same layer as the third planarization layer; and a plurality of first patterns disposed along the dam structure, wherein each of the plurality of first patterns has a planar shape including a curved line.

A display device according to one or more example embodiments of the present disclosure may include: a substrate; a display area; a non-display area configured to surround the display area; a first planarization layer disposed on the substrate; a second planarization layer disposed on the first planarization layer; a third planarization layer disposed on the second planarization layer and configured to expose a top surface of the second planarization layer; an anode disposed to cover a part of the second planarization layer and a part of the third planarization layer; a dam structure disposed in the non-display area on the substrate while surrounding the display area and including a first layer formed of a same layer as the second planarization layer, and a second layer formed of a same layer as the third planarization layer; and a plurality of patterns disposed between the dam structure and the display area along the dam structure, wherein each of the plurality of patterns has having a planar shape including a curved line.

A display device according to one or more example embodiments of the present disclosure may include: a substrate; a display area; a non-display area; one or more planarization layers disposed on the substrate, wherein the one or more planarization layers comprise a lower top surface and an upper top surface; an anode disposed on the lower top surface and a part of the upper top surface of the one or more planarization layers, wherein the lower top surface corresponds to an area including a first light-emitting area, and wherein each of the lower top surface and the upper top surface faces away from the substrate; and a dam structure disposed on the substrate and comprising one or more dam layers formed of one or more same layers as the one or more planarization layers.

A display device according to one or more example embodiments of the present disclosure may include: a substrate; a display area in which a plurality of subpixels is disposed; a non-display area; one or more planarization layers disposed on the substrate; an anode disposed on a surface of the one or more planarization layers, wherein the surface corresponds to an area including a first light-emitting area, and wherein the surface faces away from the substrate; an encapsulation layer disposed on the one or more planarization layers; and a pattern disposed on the substrate and comprising one or more pattern layers formed of one or more same layers as the one or more planarization layers, wherein: the pattern has recessed portions; and at least portions of the encapsulation layer are provided in the recessed portions.

Other detailed matters of the example embodiments are included in the detailed description and the drawings.

According to an effect of the present disclosure, it is possible to improve light extraction efficiency and reduce power consumption of the light-emitting display device by using the anode with a side mirror shape.

According to another effect of the present disclosure, it is possible to stably control a flow of the second encapsulation layer even though a large level difference occurs in accordance with the arrangement of the anode with a side mirror shape.

According to still another effect of the present disclosure, the plurality of first patterns configured to minimize a flow of the second encapsulation layer is disposed, which may minimize the optical area and the size of the bezel of the non-display area.

The effects of the present disclosure are not limited to the contents illustrated above, and more various effects are included in the present disclosure.

Additional features, advantages, and aspects of the present disclosure are set forth in part in the description that follows and in part will become apparent from the present disclosure or may be learned by practice of the inventive concepts provided herein. Other features, advantages, and aspects of the present disclosure may be realized and attained by the descriptions provided in the present disclosure, or derivable therefrom, and the claims hereof as well as the drawings. It is intended that all such features, advantages, and aspects be included within this description, be within the scope of the present disclosure, and be protected by the following claims. Nothing in this section should be taken as a limitation on those claims. Further aspects and advantages are discussed below in conjunction with embodiments of the present disclosure.

It is to be understood that both the foregoing description and the following description of the present disclosure are examples, and are intended to provide further explanation of the disclosure as claimed.

### BRIEF DESCRIPTION OF THE DRAWINGS

The accompanying drawings, which are included to provide a further understanding of the present disclosure, are incorporated in and constitute a part of this present disclosure, illustrate aspects and embodiments of the present disclosure, and together with the description serve to explain principles and examples of the disclosure. In the drawings:

FIG. 1A is a block diagram of a display device according to an example embodiment of the present disclosure;

FIG. 1B is an enlarged top plan view of one subpixel of the display device according to the example embodiment of the present disclosure;

FIG. 2 is an example of a cross-sectional view taken along line A-A′ in FIG. 1B;

FIG. 3 is an example of a cross-sectional view taken along line B-B′ in FIG. 1A;

FIG. 4 is an example of an enlarged top plan view of area C in FIG. 1A;

FIG. 5 is an example of a cross-sectional view taken along line D-D′ in FIG. 4;

FIG. 6A is a view illustrating images showing, in temporal order, results of simulating a plurality of patterns and a second encapsulation layer of a display device according to a comparative example;

FIG. 6B is a view illustrating images showing, in temporal order, results of simulating a plurality of patterns and a second encapsulation layer of the display device according to the example embodiment of the present disclosure;

FIG. 7 is an enlarged top plan view of a display device according to another example embodiment of the present disclosure;

FIGS. 8A and 8B are enlarged top plan views of a display device according to still another example embodiment of the present disclosure;

FIG. 9 is an enlarged top plan view of a display device according to yet another example embodiment of the present disclosure;

FIG. 10 is an example of a cross-sectional view taken along line E-E′ in FIG. 9; and

FIGS. 11A and 11B are enlarged top plan views of a display device according to still yet another example embodiment of the present disclosure;

FIG. 12A is an example of a cross-sectional view of area C in FIG. 1A;

FIG. 12B is an example of an enlarged view of area F in FIG. 12A;

FIG. 12C is another example of an enlarged top plan view of area C in FIG. 1A;

FIG. 13A is another example of a cross-sectional view taken along line B-B's in FIG. 1A; and

FIG. 13B is an example of a top plan view of a portion of the structure shown in FIG. 13A.

Throughout the drawings and the detailed description, unless otherwise described, the same drawing reference numerals should be understood to refer to the same elements, features, and structures. The sizes, lengths, and thicknesses of layers, regions and elements, and depiction thereof may be exaggerated for clarity, illustration, and/or convenience.

### DETAILED DESCRIPTION

Reference is now made in detail to embodiments of the present disclosure, examples of which may be illustrated in the accompanying drawings. In the following description, when a detailed description of well-known methods, functions, structures or configurations may unnecessarily obscure aspects of the present disclosure, the detailed description thereof may have been omitted for brevity. Further, repetitive descriptions may be omitted for brevity. The progression of processing steps and/or operations described is a non-limiting example.

The sequence of steps and/or operations is not limited to that set forth herein and may be changed to occur in an order that is different from an order described herein, with the exception of steps and/or operations necessarily occurring in a particular order. In one or more examples, two operations in succession may be performed substantially concurrently, or the two operations may be performed in a reverse order or in a different order depending on a function or operation involved.

Unless stated otherwise, like reference numerals may refer to like elements throughout even when they are shown in different drawings. Unless stated otherwise, the same reference numerals may be used to refer to the same or substantially the same elements throughout the specification and the drawings. In one or more aspects, identical elements (or elements with identical names) in different drawings may have the same or substantially the same functions and properties unless stated otherwise. Names of the respective elements used in the following explanations are selected only for convenience and may be thus different from those used in actual products.

Advantages and features of the present disclosure, and implementation methods thereof, are clarified through the embodiments described with reference to the accompanying drawings. The present disclosure may, however, be embodied in different forms and should not be construed as limited to the embodiments set forth herein. Rather, these embodiments are examples and are provided so that this disclosure may be thorough and complete to assist those skilled in the art to understand the inventive concepts without limiting the protected scope of the present disclosure.

Shapes, dimensions (e.g., sizes, lengths, widths, heights, thicknesses, locations, radii, diameters, and areas), proportions, ratios, angles, numbers, the number of elements, and the like disclosed herein, including those illustrated in the drawings, are merely examples, and thus, the present disclosure is not limited to the illustrated details. It is, however, noted that the relative dimensions of the components illustrated in the drawings are part of the present disclosure.

When the term “comprise,” “have,” “include,” “contain,” “constitute,” “made of,” “formed of,” “composed of,” or the like is used with respect to one or more elements (e.g., layers, films, components, structures, banks, patterns, sections, members, parts, regions, areas, portions, steps, operations, and/or the like), one or more other elements may be added unless a term such as “only” or the like is used. The terms used in the present disclosure are merely used in order to describe particular example embodiments, and are not intended to limit the scope of the present disclosure. The terms of a singular form may include plural forms unless the context clearly indicates otherwise. For example, an element may be one or more elements. An element may include a plurality of elements. The word “exemplary” is used to mean serving as an example or illustration. Embodiments are example embodiments. Aspects are example aspects. In one or more implementations, “embodiments,” “examples,” “aspects,” and the like should not be construed to be preferred or advantageous over other implementations. An embodiment, an example, an example embodiment, an aspect, or the like may refer to one or more embodiments, one or more examples, one or more example embodiments, one or more aspects, or the like, unless stated otherwise. Further, the term “may” encompasses all the meanings of the term “can.”

In one or more aspects, unless explicitly stated otherwise, an element, feature, or corresponding information (e.g., a level, range, dimension, size, or the like) is construed to include an error or tolerance range even where no explicit description of such an error or tolerance range is provided. An error or tolerance range may be caused by various factors (e.g., process factors, internal or external impact, noise, or the like). In interpreting a numerical value, the value is interpreted as including an error range unless explicitly stated otherwise.

When a positional relationship between two elements (e.g., layers, films, components, structures, banks, patterns, sections, members, parts, regions, areas, portions, and/or the like) are described using any of the terms such as “on,” “on a top of,” “upon,” “on top of,” “over,” “under,” “above,” “upper,” “at an upper portion,” “at a upper side,” “below,” “lower,” “at a lower portion,” “at a lower side,” “beneath,” “near,” “close to,” “adjacent to,” “beside,” “next to,” “at or on a side of,” and/or the like indicating a position or location, one or more other elements may be located between the two elements unless a more limiting term, such as “immediate(ly),” “direct(ly),” or “close(ly),” is used. For example, when an element and another element are described using any of the foregoing terms, this description should be construed as including a case in which the elements contact each other directly as well as a case in which one or more additional elements are disposed or interposed therebetween. Furthermore, the spatially relative terms such as the foregoing terms as well as other terms such as “front,” “rear,” “back,” “left,” “right,” “top,” “bottom,” “upper,” “lower,” “downward,” “upward,” “up,” “down,” “column,” “row,” “vertical,” “horizontal,” “diagonal,” and the like refer to an arbitrary frame of reference. For example, these terms may be used for an example understanding of a relative relationship between elements, including any correlation as shown in the drawings. However, embodiments of the disclosure are not limited thereby or thereto. The spatially relative terms are to be understood as terms including different orientations of the elements in use or in operation in addition to the orientation depicted in the drawings or described herein. For example, where a lower element or an element positioned under another element is overturned, then the element may be termed as an upper element or an element positioned above another element. Thus, for example, the term “under” or “beneath” may encompass, in meaning, the term “above” or “over.” An example term “below” or the like, can include all directions, including directions of “below,” “above” and diagonal directions. Likewise, an example term “above,” “on” or the like can include all directions, including directions of “above,” “on,” “below” and diagonal directions.

In describing a temporal relationship, when the temporal order is described as, for example, “after,” “following,” “subsequent,” “next,” “before,” “preceding,” “prior to,” or the like, a case that is not consecutive or not sequential may be included and thus one or more other events may occur therebetween, unless a more limiting term, such as “just,” “immediate(ly),” or “direct(ly),” is used.

It is understood that, although the terms “first,” “second,” and the like may be used herein to describe various elements (e.g., layers, films, components, structures, banks, patterns, sections, members, parts, regions, areas, portions, steps, operations, and/or the like), these elements should not be limited by these terms, for example, to any particular order, precedence, or number of elements. These terms are used only to distinguish one element from another. For example, a first element may denote a second element, and, similarly, a second element may denote a first element, without departing from the scope of the present disclosure. Furthermore, the first element, the second element, and the like may be arbitrarily named according to the convenience of those skilled in the art without departing from the scope of the present disclosure. For clarity, the functions or structures of these elements (e.g., the first element, the second element, and the like) are not limited by ordinal numbers or the names in front of the elements. Further, a first element may include one or more first elements. Similarly, a second element or the like may include one or more second elements or the like.

In describing elements of the present disclosure, the terms “first,” “second,” “A,” “B,” “(a),” “(b),” or the like may be used. These terms are intended to identify the corresponding element(s) from the other element(s), and these are not used to define the essence, basis, order, or number of the elements.

The expression that an element (e.g., layer, film, component, structure, bank, pattern, section, member, part, region, area, portion, or the like) “is engaged” with another element may be understood, for example, as that the element may be either directly or indirectly engaged with the another element. The term “is engaged” or similar expressions may refer to a term such as “is enclosed,” “is surrounded,” “covers,” “is in contact,” “overlaps,” “crosses,” “intersects,” “is connected,” “is coupled,” “is attached,” “is adhered,” “is combined,” “is linked,” “is provided,” “is disposed,” “interacts,” or the like. The engagement may involve one or more intervening elements disposed or interposed between the element and the another element, unless otherwise specified. Further, the element may be engaged at least partially or entirely (or completely) with the another element, unless otherwise specified. Further, the element may be included in at least one of two or more elements that are engaged with each other. Similarly, the another element may be included in at least one of two or more elements that are engaged with each other. When the element is engaged with the another element, at least a portion of the element may be engaged with at least a portion of the another element. The term “with another element” or similar expressions may be understood as “another element,” or “with, to, in, or on another element,” as appropriate by the context. Similarly, the term “with each other” may be understood as “each other,” or “with, to, or on each other,” as appropriate by the context.

The phrase “through” may be understood, for example, to be at least partially through or entirely through.

The terms such as a “line” or “direction” should not be interpreted only based on a geometrical relationship in which the respective lines or directions are parallel, perpendicular, diagonal, or slanted with respect to each other, and may be meant as lines or directions having wider directivities within the range within which the components of the present disclosure may operate functionally.

The term “at least one” should be understood as including any and all combinations of one or more of the associated listed items. For example, each of the phrases “at least one of a first item, a second item, or a third item” and “at least one of a first item, a second item, and a third item” may represent (i) a combination of items provided by two or more of the first item, the second item, and the third item or (ii) only one of the first item, the second item, or the third item. Further, at least one of a plurality of elements can represent (i) one element of the plurality of elements, (ii) some elements of the plurality of elements, or (iii) all elements of the plurality of elements. Further, “at least some,” “at least some portions,” “at least some parts,” “at least a portion,” “at least one or more portions,” “at least a part,” “at least one or more parts,” “at least some elements,” “one or more,” or the like of a plurality of elements can represent (i) one element of the plurality of elements, (ii) a portion (or a part) of the plurality of elements, (iii) one or more portions (or parts) of the plurality of elements, (iv) multiple elements of the plurality of elements, or (v) all of the plurality of elements. Moreover, “at least some,” “at least some portions,” “at least some parts,” “at least a portion,” “at least one or more portions,” “at least a part,” “at least one or more parts,” or the like of an element can represent (i) a portion (or a part) of the element, (ii) one or more portions (or parts) of the element, or (iii) the element, or all portions of the element.

The expression of a first element, a second elements “and/or” a third element should be understood as one of the first, second and third elements or as any or all combinations of the first, second and third elements. By way of example, A, B and/or C may refer to only A; only B; only C; any of A, B, and C (e.g., A, B, or C); some combination of A, B, and C (e.g., A and B; A and C; or B and C); or all of A, B, and C. Furthermore, an expression “A/B” may be understood as A and/or B. For example, an expression “A/B” may refer to only A; only B; A or B; or A and B.

In one or more aspects, the terms “between” and “among” may be used interchangeably simply for convenience unless stated otherwise. For example, an expression “between a plurality of elements” may be understood as among a plurality of elements. In another example, an expression “among a plurality of elements” may be understood as between a plurality of elements. In one or more examples, the number of elements may be two. In one or more examples, the number of elements may be more than two. Furthermore, when an element is referred to as being “between” at least two elements, the element may be the only element between the at least two elements, or one or more intervening elements may also be present.

In one or more aspects, the phrases “each other” and “one another” may be used interchangeably simply for convenience unless stated otherwise. For example, an expression “different from each other” may be understood as being different from one another. In another example, an expression “different from one another” may be understood as being different from each other. In one or more examples, the number of elements involved in the foregoing expression may be two. In one or more examples, the number of elements involved in the foregoing expression may be more than two.

In one or more aspects, the phrases “one or more among” and “one or more of” may be used interchangeably simply for convenience unless stated otherwise.

The term “or” means “inclusive or” rather than “exclusive or.” That is, unless otherwise stated or clear from the context, the expression that “x uses a or b” means any one of natural inclusive permutations. For example, “a or b” may mean “a,” “b,” or “a and b.” For example, “a, b or c” may mean “a,” “b,” “c,” “a and b,” “b and c,” “a and c,” or “a, b and c.”

A phrase “substantially the same” or “nearly the same” may indicate a degree of being considered as being equivalent to each other taking into account minute differences due to errors in the manufacturing process.

Features of various embodiments of the present disclosure may be partially or entirely coupled to or combined with each other, may be technically associated with each other, and may be variously operated, linked or driven together in various ways. Embodiments of the present disclosure may be implemented or carried out independently of each other or may be implemented or carried out together in a co-dependent or related relationship. In one or more aspects, the components of each apparatus and device according to various embodiments of the present disclosure are operatively coupled and configured.

Unless otherwise defined, the terms (including technical and scientific terms) used herein have the same meaning as commonly understood by one of ordinary skill in the art to which example embodiments belong. It is further understood that terms, such as those defined in commonly used dictionaries, should be interpreted as having a meaning that is, for example, consistent with their meaning in the context of the relevant art and should not be interpreted in an idealized or overly formal sense unless expressly defined otherwise herein.

The terms used herein have been selected as being general in the related technical field; however, there may be other terms depending on the development and/or change of technology, convention, preference of technicians, and so on. Therefore, the terms used herein should not be understood as limiting technical ideas, but should be understood as examples of the terms for describing example embodiments.

Further, in a specific case, a term may be arbitrarily selected by an applicant, and in this case, the detailed meaning thereof is described herein. Therefore, the terms used herein should be understood based on not only the name of the terms, but also the meaning of the terms and the content hereof.

In the following description, various example embodiments of the present disclosure are described in more detail with reference to the accompanying drawings. With respect to reference numerals to elements of each of the drawings, the same elements may be illustrated in other drawings, and like reference numerals may refer to like elements unless stated otherwise. The same or similar elements may be denoted by the same reference numerals even though they are depicted in different drawings. In addition, for the convenience of description, a scale, dimension, size, and thickness of each of the elements illustrated in the accompanying drawings may be different from an actual scale, dimension, size, and thickness, and thus, embodiments of the present disclosure are not limited to a scale, dimension, size, and thickness illustrated in the drawings.

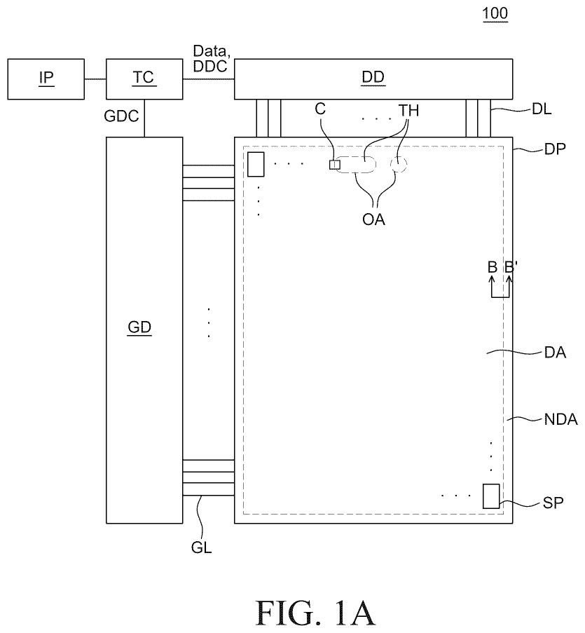

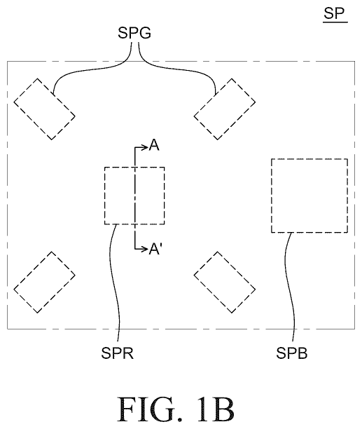

FIG. 1A is a block diagram of a display device according to an example embodiment of the present disclosure.

With reference to FIG. 1A, a display device 100 according to an example embodiment of the present disclosure may include an image processor IP, a timing controller TC, a data driver DD, a gate driver GD, and a display panel DP.

In this case, the image processor IP may output a data signal, a data enable signal, and the like supplied from the outside. The image processor IP may output one or more of a vertical synchronizing signal, a horizontal synchronizing signal, and a clock signal in addition to the data enable signal.

The timing controller TC receives the data signal in addition to the data enable signal or the driving signals including the vertical synchronizing signal, the horizontal synchronizing signal, and the clock signal from the image processor IP. On the basis of the driving signal, the timing controller TC may output a gate timing control signal GDC for controlling an operation timing of the gate driver GD, output a data timing control signal DDC for controlling an operation timing of the data driver GD, and output a data signal Data.

In addition, in response to the data timing control signal DDC supplied from the timing controller TC, the data driver DD may sample and latch the data signal Data supplied from the timing controller TC, convert the data signal Data into a gamma reference voltage, and output the gamma reference voltage. The data driver DD may output the data signal through plurality of data lines DL.

In addition, the gate driver GD may output the gate signal while shifting a level of the gate voltage in response to the gate timing control signal GDC supplied from the timing controller TC. The gate driver GD outputs the gate signal through the plurality of gate lines GL.

The display panel DP may display an image as a subpixel SP emits light in response to the data signal and the gate signal supplied from the data driver DD and the gate driver GD.

The display panel DP may include a display area DA, and a non-display area NDA configured to surround the display area DA.

The display area DA is an area of the display panel DP in which images are displayed.

A plurality of subpixels SP and a circuit for operating the plurality of subpixels SP may be disposed in the display area DA. The plurality of subpixels SP may be minimum units that constitute the display area DA. Display elements may be respectively disposed in the plurality of subpixels SP. For example, an organic light-emitting element including an anode, a light-emitting layer, and a cathode may be disposed in each of the plurality of subpixels SP. However, the present disclosure is not limited thereto. In addition, the circuit configured to operate the plurality of subpixels SP may include driving elements, lines, and the like. For example, the circuit may include a transistor, a storage capacitor, a gate line, a data line, and the like. However, the present disclosure is not limited thereto.

An optical area OA is an area disposed in the display area DA, and one or more through-holes TH may be disposed in the optical area OA. The through-hole TH may be disposed in the display area DA of the display panel DP, thereby reducing a bezel area, which is the non-display area NDA, and maximizing the display area DA. A design product with the maximized display area DA maximizes a degree of screen immersion of a user, thereby improving an aesthetic appearance.

The through-hole TH may be formed to correspond to an optical electronic device such as a camera or optical sensor.

FIG. 1A illustrates two through-holes TH. However, the present disclosure is not limited thereto. The number of through-holes TH variously may be provided. For example, one or two holes are disposed in the display area DA. A camera may be disposed in a first hole, and a distance detection sensor, a face recognition sensor, or a wide angle camera may be disposed in a second hole.

The non-display area NDA is an area in which no image is displayed.

The non-display area NDA may be bent, such that the non-display area NDA is not visible from a front surface. Alternatively, for example, the non-display area NDA may be covered by a casing or the like that constitutes an outer periphery of the display device. The non-display area NDA is called a bezel area.

FIG. 1A illustrates that the non-display area NDA surrounds the display area DA having a quadrangular shape. However, the shapes and arrangements of the display area DA and the non-display area NDA are not limited to the example illustrated in FIG. 1A. That is, the display area DA and the non-display area NDA may be suitable for the design of an electronic device equipped with the display device 100. For example, an example shape of the display area DA may also be a pentagonal shape, a hexagonal shape, a circular shape, an elliptical shape, or the like.

Various lines and circuits for operating the organic light-emitting element in the display area DA may be disposed in the non-display area NDA. For example, the non-display area NDA may include link lines for transmitting signals to the plurality of subpixels and the circuit in the display area DA. The non-display area NDA may include gate-in-panel (GIP) lines or drive integrated circuits (ICs) such as the gate driver GD and the data driver DD. However, the present disclosure is not limited thereto.

The display device 100 may further include various additional elements configured to generate various signals or operate a pixel in the display area DA. The additional elements for operating the pixel may include an inverter circuit, a multiplexer, an electrostatic discharge (ESD) circuit, and the like. The display device 100 may also include additional elements related to functions other than the function of operating the pixel. For example, the display device 100 may further include additional elements that provide a touch detection function, a user certification function (e.g., fingerprint recognition), a multi-level pressure detection function, a tactile feedback function, and the like. The above-mentioned additional elements may be positioned in the non-display area NDA and/or an external circuit connected to a connection interface.

FIG. 1B is an enlarged top plan view of one subpixel of the display device according to the example embodiment of the present disclosure.

With reference to FIG. 1B, the plurality of subpixels SP includes a plurality of subpixels SPR, SPG, and SPB that emits light beams with different colors. The plurality of subpixels SP may include a red subpixel SPR configured to emit red light, a green subpixel SPG configured to emit green light, and a blue subpixel SPB configured to emit blue light. The plurality of subpixels SP may further include a white subpixel configured to emit white light. However, the present disclosure is not limited thereto.

For example, four green subpixels SPG, one red subpixel SPR, and one blue subpixel SPB may be disposed in one subpixel SP (or one pixel). One red subpixel SPR or one blue subpixel SPB may be disposed at a center of the four green subpixels SPG disposed at an imaginary quadrangular edge. Further, the blue subpixel SPB may be larger in area than the red subpixel SPR. However, the arrangement relationship between the plurality of subpixels SPR, SPG, and SPB is not limited thereto and may be variously changed in accordance with the necessity of design.

Meanwhile, the plurality of subpixels SPR, SPG, and SPB may have different shapes in a plan view. The light-emitting areas of the plurality of subpixels SPR, SPG, and SPB may have different shapes in a plan view. For example, in a plan view, the shapes of the light-emitting areas of the red subpixel SPR and the blue subpixel SPB may each be a polygonal shape such as a quadrangular or octagonal shape. For example, in a plan view, the shape of the light-emitting area of the green subpixel SPG may be a polygonal shape such as a quadrangular shape (e.g., a square shape or a rectangle shape) or an octagonal shape. However, the present disclosure is not limited thereto.

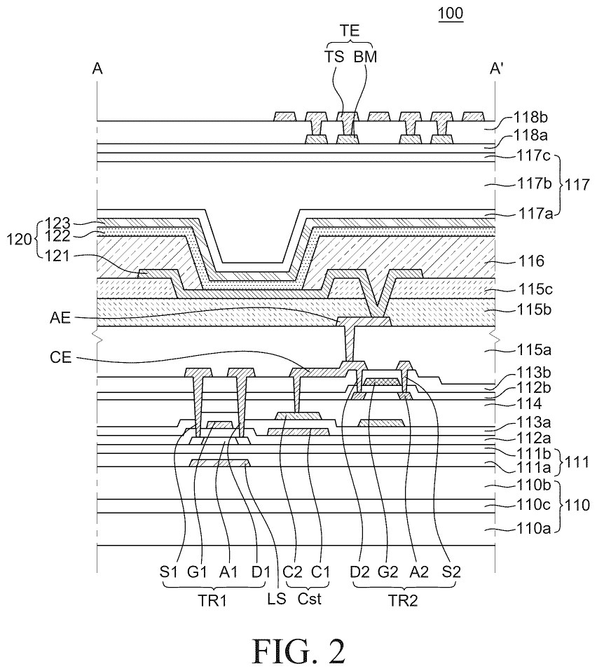

Hereinafter, a cross-sectional structure of the display area DA of the display device 100 will be described in more detail with reference to FIG. 2.

FIG. 2 is an example of a cross-sectional view taken along line A-A′ in FIG. 1B. FIG. 2 is an example of a cross-sectional view for explaining a cross-sectional structure of one subpixel SP of the display device 100 according to the example embodiment of the present disclosure. Hereinafter, in order to avoid a repeated description, a cross-sectional structure of one subpixel SP will be described with reference to a first subpixel SP1 among the plurality of subpixels SP as an example.

With reference to FIG. 2, the display device 100 according to the example embodiment of the present disclosure may include a substrate 110, a lower buffer layer 111, a first transistor TR1, a storage capacitor Cst, a first gate insulation layer 112a, a first interlayer insulation layer 113a, an upper buffer layer 114, a second transistor TR2, a second gate insulation layer 112b, a second interlayer insulation layer 113b, a connection electrode CE, a first planarization layer 115a, an auxiliary electrode AE, a second planarization layer 115b, a third planarization layer 115c, a bank 116, a light-emitting element 120, an encapsulation part 117, a touch buffer layer 118a, a touch interlayer insulation layer 118b, and a touch electrode TE.

The substrate 110 serves to support and protect constituent elements of the display device 100 that are disposed above the substrate 110.

The substrate 110 is a component for supporting various constituent elements included in the display device 100 and may be made of an insulating material. The substrate 110 may include a first substrate 110a, a second substrate 110b, and an inorganic insulation layer 110c. The inorganic insulation layer 110c may be disposed between the first substrate 110a and the second substrate 110b. As described above, the substrate 110 includes a triple layer including the first substrate 110a, the second substrate 110b, and the inorganic insulation layer 110c, thereby minimizing moisture penetration from the outside. However, the substrate 110 may be disposed as a single layer. However, the present disclosure is not limited thereto.

The first substrate 110a may have rigidity and flexibility. Among the components of the substrate 110, the first substrate 110a may be configured to substantially support the constituent elements of the display device 100. For example, the first substrate 110a may be a flexible substrate made of polyimide (PI). However, the present disclosure is not limited thereto.

The inorganic insulation layer 110c is disposed on an entire surface of the first substrate 110a. The inorganic insulation layer 110c may be made of an inorganic insulating material. For example, the inorganic insulation layer 110c may be configured as a single layer or multilayer made of silicon nitride (SiNx) or silicon oxide (SiOx). However, the present disclosure is not limited thereto.

The second substrate 110b is disposed on the inorganic insulation layer 110c. The second substrate 110b may have rigidity and flexibility. Among the components of the substrate 110, the second substrate 110b, together with the first substrate 110a, may be configured to substantially support the constituent elements of the display device 100. For example, the second substrate 110b may be a flexible substrate made of polyimide (PI). However, the present disclosure is not limited thereto.

The lower buffer layer 111 is disposed on the substrate 110. The lower buffer layer 111 may be disposed below the first transistor TR1 and delay the diffusion of moisture or oxygen, which penetrates into the substrate 110, to the first transistor TR1.

The lower buffer layer 111 may include a first lower buffer layer 111a and a second lower buffer layer 111b. The lower buffer layer 111 may be configured as a multilayer including the first lower buffer layer 111a and the second lower buffer layer 111b. Therefore, the lower buffer layer 111 may be called a multi-buffer layer. However, the lower buffer layer 111 may be configured as a single layer or include a plurality of layers other than two layers. However, the present disclosure is not limited thereto.

The first lower buffer layer 111a may be configured as a single layer or multilayer made of any one of amorphous silicon (a-Si), silicon nitride (SiNx), and silicon oxide (SiOx). However, the present disclosure is not limited thereto.

The second lower buffer layer 111b may be configured as a single layer or multilayer made of any one of amorphous silicon (a-Si), silicon nitride (SiNx), and silicon oxide (SiOx). However, the present disclosure is not limited thereto.

The first transistor TR1 is disposed on the lower buffer layer 111. The first transistor TR1 may include a first active layer A1, a first gate electrode G1, a first source electrode S1, and a first drain electrode D1. However, in accordance with the design of the pixel circuit, the first source electrode S1 may be the first drain electrode D1, and the first drain electrode D1 may be the first source electrode S1.

The first active layer A1 is disposed on the lower buffer layer 111. The first active layer A1 may include amorphous silicon or low-temperature polysilicon (low-temperature polycrystalline silicon (LTPS)) such as polysilicon (polycrystalline silicon).

For example, the first active layer A1 may include low-temperature polysilicon (LTPS). Because a polysilicon material has high mobility (100 cm²/Vs or more), low energy power consumption, and excellent reliability, the polysilicon material may be applied to gate drivers and/or multiplexers (MUX) for driving elements for operating transistors for light-emitting elements. Therefore, the first active layer A1 including low-temperature polysilicon (LTPS) may be applied to the active layer of the driving transistor. However, the present disclosure is not limited thereto.

For example, the first active layer A1 may include a channel area in which a channel is formed when the first transistor TR1 operates, and a source area and a drain area disposed at two opposite sides of the channel area. The source area means a portion of the first active layer A1 connected to the first source electrode S1, and the drain area means a portion of the first active layer A1 connected to the first drain electrode D1. For example, the source area and the drain area may be configured by doping the first active layer A1 with ions (impurities). The source area and the drain area may be formed by doping the polysilicon material with ions. The channel area may mean a portion in which the polysilicon material remains without being subjected to the ion doping.

The first gate insulation layer 112a may be disposed on the first active layer A1. The first gate insulation layer 112a may be configured as a single layer made of silicon nitride (SiNx) or silicon oxide (SiOx) or a multilayer including the above-mentioned layers. The first gate insulation layer 112a may have contact holes through which the first source electrode S1 and the first drain electrode D1 of the first transistor TR1 are respectively connected to the source area and the drain area of the first active layer A1 of the first transistor TR1.

The first gate electrode G1 of the first transistor TR1 is disposed on the first gate insulation layer 112a.

For example, the first gate electrode G1 may be configured as a single layer or multilayer made of any one of molybdenum (Mo), copper (Cu), titanium (Ti), aluminum (Al), chromium (Cr), gold (Au), nickel (Ni), and neodymium (Nd) or an alloy thereof. However, the present disclosure is not limited thereto. The first gate electrode G1 may be formed on the first gate insulation layer 112a so as to overlap the channel area of the first active layer A1 of the first transistor TR1.

Meanwhile, a first capacitor electrode C1 of the storage capacitor Cst may be disposed on the first gate insulation layer 112a. For example, the first capacitor electrode C1 may be configured as a single layer or multilayer made of any one of molybdenum (Mo), copper (Cu), titanium (Ti), aluminum (Al), chromium (Cr), gold (Au), nickel (Ni), and neodymium (Nd) or an alloy thereof. However, the present disclosure is not limited thereto.

The first capacitor electrode C1 may be excluded on the basis of the operating properties of the display device 100 and the structure, type, and the like of the transistor. The first gate electrode G1 and the first capacitor electrode C1 may be formed by the same process. Further, the first gate electrode G1 and the first capacitor electrode C1 may be made of the same material and formed on the same layer.

The first interlayer insulation layer 113a may be disposed on the first gate insulation layer 112a and the first gate electrode G1. The first interlayer insulation layer 113a may have a contact hole through which the first source area and the first drain area of the first active layer A1 of the first transistor TR1 are exposed. For example, the first interlayer insulation layer 113a may be configured as a single layer made of silicon nitride (SiNx) or silicon oxide (SiOx) or a multilayer including the above-mentioned layers.

A second capacitor electrode C2 of the storage capacitor Cst may be disposed on the first interlayer insulation layer 113a. The second capacitor electrode C2 may be configured as a single layer or multilayer made of any one of molybdenum (Mo), copper (Cu), titanium (Ti), aluminum (Al), chromium (Cr), gold (Au), nickel (Ni), neodymium (Nd), and an alloy thereof.

The second capacitor electrode C2 may be formed on the first interlayer insulation layer 113a so as to overlap the first capacitor electrode C1. In addition, the second capacitor electrode C2 may be made of the same material as the first capacitor electrode C1. The second capacitor electrode C2 may be excluded on the basis of the operating properties of the display device 100 and the structure, type, and the like of the transistor. However, the present disclosure is not limited thereto.

The upper buffer layer 114 is disposed on the first interlayer insulation layer 113a. The upper buffer layer 114 may include a first upper buffer layer 114a and a second upper buffer layer 114b. The upper buffer layer 114 may be configured as a multilayer including the first upper buffer layer 114a and the second upper buffer layer 114b. Therefore, the upper buffer layer 114 may be called a multi-buffer layer. However, the upper buffer layer 114 may be configured as a single layer or include a plurality of layers other than two layers. However, the present disclosure is not limited thereto.

The first upper buffer layer 114a may be configured as a single layer or multilayer made of any one of amorphous silicon (a-Si), silicon nitride (SiNx), and silicon oxide (SiOx). However, the present disclosure is not limited thereto.

The second upper buffer layer 114b may be configured as a single layer or multilayer made of any one of amorphous silicon (a-Si), silicon nitride (SiNx), and silicon oxide (SiOx). However, the present disclosure is not limited thereto.

The second transistor TR2 is disposed on the upper buffer layer 114. The second transistor TR2 may include a second active layer A2, a second gate electrode G2, a second source electrode S2, and a second drain electrode D2. However, in accordance with the design of the pixel circuit, the second source electrode S2 may be the drain electrode, and the second drain electrode D2 may be the second source electrode S2.

The second active layer A2 is disposed on the upper buffer layer 114. The second active layer A2 may include an oxide semiconductor material made of metal oxide such as indium-gallium-zinc-oxide (IGZO), indium-zinc-oxide (IZO), indium-gallium-tin-oxide (IGTO), or indium-gallium-oxide (IGO).

For example, the second active layer A2 may be made of an oxide semiconductor. The oxide semiconductor material is a material having a larger band gap than a silicon material and has a low off-current because electrons cannot pass through the band gap in an OFF state. Therefore, the transistor including the active layer made of the oxide semiconductor may be suitable for a switching transistor that maintains the short ON time and the long OFF time. However, the present disclosure is not limited thereto.

For example, the second active layer A2 may include a channel area in which a channel is formed when the second transistor TR2 operates, and a source area and a drain area disposed at two opposite sides of the channel area. The source area means a portion of the second active layer A2 connected to the second source electrode S2, and the drain area means a portion of the second active layer A2 connected to the second drain electrode D2. For example, the source area and the drain area may be configured by doping the second active layer A2 with ions (impurities). The source area and the drain area may be formed by doping the oxide semiconductor material with ions. The channel area may mean a portion in which the oxide semiconductor material remains without being subjected to the ion doping.

The second gate insulation layer 112b may be disposed on the second active layer A2. The second gate insulation layer 112b may be configured as a single layer made of silicon nitride (SiNx) or silicon oxide (SiOx) or a multilayer including the above-mentioned layers. The second gate insulation layer 112b may have contact holes through which the second source electrode S2 and the second drain electrode D2 of the second transistor TR2 are respectively connected to the source area and the drain area of the second active layer A2 of the second transistor TR2.

The second gate electrode G2 of the second transistor TR2 is disposed on the second gate insulation layer 112b.

For example, the second gate electrode G2 may be configured as a single layer or multilayer made of any one of molybdenum (Mo), copper (Cu), titanium (Ti), aluminum (Al), chromium (Cr), gold (Au), nickel (Ni), and neodymium (Nd) or an alloy thereof. However, the present disclosure is not limited thereto. The second gate electrode G2 may be formed on the second gate insulation layer 112b so as to overlap the channel area of the second active layer A2 of the second transistor TR2.

The second interlayer insulation layer 113b may be disposed on the second gate insulation layer 112b and the second gate electrode G2. The second interlayer insulation layer 113b may be configured as a single layer made of silicon nitride (SiNx) or silicon oxide (SiOx) or a multilayer including the above-mentioned layers.

The first source electrode S1, the first drain electrode D1, the second source electrode S2, the second drain electrode D2, and the connection electrode CE are disposed on the second interlayer insulation layer 113b.

The first source electrode S1 and the first drain electrode D1 may be electrically connected to the first active layer A1 of the first transistor TR1 through the contact holes of the first gate insulation layer 112a, the first interlayer insulation layer 113a, the upper buffer layer 114, the second gate insulation layer 112b, and the second interlayer insulation layer 113b.

The second source electrode S2 and the second drain electrode D2 may be electrically connected to the second active layer A2 of the second transistor TR2 through the contact holes of the second gate insulation layer 112b and the second interlayer insulation layer 113b.

For example, the first source electrode S1, the first drain electrode D1, the second source electrode S2, and the second drain electrode D2 may each be configured as a single layer or multilayer made of any one of molybdenum (Mo), copper (Cu), titanium (Ti), aluminum (Al), chromium (Cr), gold (Au), nickel (Ni), and neodymium (Nd) or an alloy thereof. However, the present disclosure is not limited thereto.

The connection electrode CE may be electrically connected to the second drain electrode D2 of the second transistor TR2. Further, the connection electrode CE may be electrically connected to the second capacitor electrode C2 of the storage capacitor Cst through contact holes formed in the second buffer layer 114 and the second interlayer insulation layer 113b. That is, the connection electrode CE may serve to electrically connect the second capacitor electrode C2 of the storage capacitor Cst and the second drain electrode D2 of the second transistor TR2.

Meanwhile, the connection electrode CE may be formed by the same process and made of the same material as the first source electrode S1 and the first drain electrode D1 of the first transistor TR1 and the second source electrode S2 and the second drain electrode D2 of the second transistor TR2. For example, the connection electrode CE may be configured as a single layer or multilayer made of any one of molybdenum (Mo), copper (Cu), titanium (Ti), aluminum (Al), chromium (Cr), gold (Au), nickel (Ni), and neodymium (Nd) or an alloy thereof. However, the present disclosure is not limited thereto.

In addition, the connection electrode CE may be integrally connected to the second drain electrode D2 of the second transistor TR2. However, the present disclosure is not limited thereto.

Meanwhile, with reference to FIG. 2, in the first transistor TR1 and the second transistor TR2, light-blocking layers LS are respectively disposed below the first active layer A1 and the second active layer A2. The light-blocking layer LS may be disposed between the substrate 110 and the lower buffer layer 111 so as to overlap the first active layer A1, and the light-blocking layer LS may be disposed between the first interlayer insulation layer 113a and the upper buffer layer 114 so as to overlap the second active layer A2. Therefore, the light-blocking layer LS may be insulated from the first active layer A1 and the second active layer A2.

The light-blocking layer LS may be made of a metallic material with low light transmittance. The light-blocking layers LS may be disposed below the first active layer A1 and the second active layer A2 and reflect light entering the first active layer A1 and the second active layer A2. The light-blocking layers LS may block light entering the first active layer A1 and the second active layer A2 and protect the first active layer A1 and the second active layer A2. For example, the light-blocking layer LS may be called bottom shield metal (BSM). However, the present disclosure is not limited thereto. For example, the light-blocking layer LS may be configured as a single layer or multilayer made of any one of molybdenum (Mo), copper (Cu), titanium (Ti), aluminum (Al), chromium (Cr), gold (Au), nickel (Ni), and neodymium (Nd) or an alloy thereof. However, the present disclosure is not limited thereto.

The first planarization layer 115a may be disposed on the connection electrode CE, the first source electrode S1 and the first drain electrode D1 of the first transistor TR1, the second source electrode S2 and the second drain electrode D2 of the second transistor TR2, the second interlayer insulation layer 113b.

The first planarization layer 115a may be an organic layer for planarizing and protecting an upper portion of the first transistor TR1 and an upper portion of the second transistor TR2. For example, the first planarization layer 115a may be made of an organic material such as acrylic resin, epoxy resin, phenolic resin, polyamide resin, and polyimide resin.

The auxiliary electrode AE is disposed on the first planarization layer 115a. The auxiliary electrode AE may be connected to the second drain electrode D2 of the second transistor TR2 through a contact hole of the first planarization layer 115a. Therefore, the auxiliary electrode AE may be configured to electrically connect the second transistor TR2 and the light-emitting element 120.

For example, the auxiliary electrode AE may be configured as a single layer or multilayer made of any one of molybdenum (Mo), copper (Cu), titanium (Ti), aluminum (Al), chromium (Cr), gold (Au), nickel (Ni), and neodymium (Nd) or an alloy thereof. However, the present disclosure is not limited thereto.

The second planarization layer 115b is disposed on the first planarization layer 115a and the auxiliary electrode AE. A top surface of the second planarization layer 115b is a surface parallel to the substrate 110. Therefore, the second planarization layer 115b may eliminate a level difference that may occur because of constituent elements disposed below the second planarization layer 115b. For example, the second planarization layer 115b may be made of an organic material such as acrylic resin, epoxy resin, phenolic resin, polyamide resin, and polyimide resin. However, the present disclosure is not limited thereto.

The third planarization layer 115c is disposed on the second planarization layer 115b. The top surface of the second planarization layer 115b is disposed to be exposed in areas corresponding to the light-emitting areas of the plurality of subpixels SP. For example, the third planarization layer 115c may be provided as a plurality of third planarization layers 115c disposed in shapes protruding from a top surface of the second planarization layer 115b after the second planarization layer 115b with the flat top surface is formed.

The third planarization layer 115c includes a top surface and a side surface. The top surface of the third planarization layer 115c may be a surface positioned on an uppermost portion of the third planarization layer 115c. The top surface of the third planarization layer 115c may be a surface substantially parallel to the second planarization layer 115b or the substrate 110. That is, the top surface of the third planarization layer 115c may be flat. The side surface of the third planarization layer 115c may be a surface extending from the top surface of the third planarization layer 115c toward the top surface of the second planarization layer 115b. The side surface of the third planarization layer 115c may have a shape inclined from the top surface of the third planarization layer 115c toward the second planarization layer 115b. Therefore, the third planarization layer 115c may have a shape in which a top surface thereof is smaller than a bottom surface thereof. For example, the side surface of the third planarization layer 115c may have a tapered shape. However, the present disclosure is not limited thereto.

The light-emitting element 120 is disposed on the third planarization layer 115c.

The light-emitting element 120 includes an anode 121, a light-emitting layer 122, and a cathode 123.

The anode 121 is disposed on the third planarization layer 115c. The anode 121 may be connected to the auxiliary electrode AE through the contact holes of the second planarization layer 115b and the third planarization layer 115c and electrically connected to the second transistor TR2. The anode 121 may be made of a metallic material.

In case that the display device 100 is a top-emission type display device in which light emitted from the light-emitting element 120 propagates toward an upper side of the substrate 110 on which the light-emitting element 120 is disposed, the anode 121 may include a reflective layer, and a transparent conductive layer disposed on the reflective layer. For example, the transparent conductive layer may be made of transparent conductive oxide such as indium tin oxide (ITO) or indium zinc oxide (IZO). For example, the transparent conductive layer may be made of silver (Ag), aluminum (Al), gold (Au), molybdenum (Mo), tungsten (W), chromium (Cr), or an alloy thereof. However, the present disclosure is not limited thereto.

The anode 121 is disposed to correspond to each of the plurality of subpixels SP. The anode 121 is disposed to cover the second planarization layer 115b and the third planarization layer 115c. The anode 121 may be disposed along a shape of the second planarization layer 115b and a shape of the third planarization layer 115c. Specifically, the anode 121 may be disposed on the top surface of the second planarization layer 115b and the side surface of the third planarization layer 115c on which the third planarization layer 115c is not disposed. In addition, the anode 121 may also be formed in a partial area of the top surface of the third planarization layer 115c. That is, the anode 121 may be disposed flat on the top surface of the third planarization layer 115c.

Meanwhile, the anode 121 may be disposed on the top surface of the second planarization layer 115b and the side surface of the third planarization layer 115c and configured to have a side mirror structure. Therefore, the anode 121 disposed on an inclined side surface of the third planarization layer 115c may reflect the light emitted from the light-emitting layer 122 and extract the light to the outside of the display device 100, thereby improving the light extraction efficiency of the light-emitting element 120.

Meanwhile, in the display device in which the anode 121 is configured to have the side mirror structure, the plurality of subpixels SP may include a plurality of light-emitting areas and at least one non-light-emitting area. For example, the plurality of light-emitting areas may include a first light-emitting area, and a second light-emitting area configured to surround the first light-emitting area. The non-light-emitting area may include a first non-light-emitting area disposed between the first light-emitting area and the second light-emitting area, and a second non-light-emitting area configured to surround the second light-emitting area.

The first light-emitting area may correspond to an area in which the top surface of the anode 121 is exposed by the bank 116. That is, the first light-emitting area may be an area in which a part of the light emitted from the light-emitting layer 122 is extracted to the outside of the display device 100 through the light-emitting layer 122 and the cathode 123.

The first light-emitting area may be surrounded by the first non-light-emitting area. The first non-light-emitting area may be an area in which a part of the light emitted from the light-emitting layer 122 reaches the bank 116 and cannot be extracted to the outside of the display device 100. The first non-light-emitting area may correspond to an area in which the anode 121 disposed on the top surface of the second planarization layer 115b is covered by the bank 116.

When the display device 100 is in an on-state, the first non-light-emitting area may be in a black state or appear to emit light because of the light introduced from at least one of the first light-emitting area and the second light-emitting area. However, the first non-light-emitting area may be in a state lower in luminance than the first light-emitting area and the second light-emitting area.

The first non-light-emitting area may be surrounded by the second light-emitting area. The second light-emitting area may correspond to an area in which the anode 121 is disposed on the inclined surface of the third planarization layer 115c. That is, the second light-emitting area may be an area in which a part of the light emitted from the light-emitting layer 122 is reflected by the anode 121 disposed on the inclined surface of the third planarization layer 115c, and the light is extracted to the outside of the display device 100.

The second light-emitting area may be surrounded by the second non-light-emitting area. The second non-light-emitting area may be connected to or correspond to an area in which the anode 121 is disposed on the flat top surface of the third planarization layer 115c. Meanwhile, the constituent elements for operating the light-emitting areas may be disposed in the second non-light-emitting area. For example, a contact hole may be disposed in the second non-light-emitting area of the anode 121 to connect the anode 121 and the auxiliary electrode AE. However, the present disclosure is not limited thereto.

When the display device 100 is in an on-state, the second non-light-emitting area may be in a black state or appear to emit light because of the light introduced from at least one of the first light-emitting area and the second light-emitting area. However, the second non-light-emitting area may be in a state lower in luminance than the first light-emitting area and the second light-emitting area.

The bank 116 is disposed on the anode 121. The bank 116 may be disposed while covering an end of the anode 121. A portion of the bank 116, which corresponds to the light-emitting area of the subpixel SP, may be opened. A part of the anode 121 may be exposed through the opened portion (hereinafter, referred to as an open area) of the bank 116. In this case, the bank 116 may be made of an inorganic insulating material such as silicon nitride (SiNx) or silicon oxide (SiOx), or an organic insulating material such as benzocyclobutene-based resin, acrylic resin, or imide-based resin. However, the present disclosure is not limited thereto. The light-emitting layer 122 is disposed on the anode 121 and the bank 116. The light-emitting layer 122 may be disposed in the open area of the bank 116 and an area at the periphery of the open area. Therefore, the light-emitting layer 122 may be disposed on the anode 121 exposed through the open area of the bank 116.

The light-emitting layer 122 may include a plurality of organic material layers. For example, the light-emitting layer 122 may include organic material layers such as a hole injection layer, a hole transport layer, an electron transport layer, and an electron injection layer. Meanwhile, in case that the light-emitting layer 122 is the light-emitting layer 122 configured to emit white light, the light beam emitted from the light-emitting layer 122 may be converted into light beams with various colors by a plurality of color filters. However, the present disclosure is not limited thereto.

The cathode 123 is disposed on the light-emitting layer 122. Because the cathode 123 supplies electrons to the light-emitting layer 122, the cathode 123 may be made of an electrically conductive material having a low work function. The cathode 123 may be configured as a single layer over the plurality of subpixels SP. That is, the cathodes 123 of the plurality of subpixels SP may be connected to and integrated with one another.

For example, the cathode 123 may be made of an electrically transparent conductive material such as indium tin oxide (ITO) or indium zinc oxide (IZO) or made of an alloy of ytterbium (Yb). The cathode 123 may further include a metal doping layer. However, the present disclosure is not limited thereto.

An encapsulation layer 117 is disposed on the light-emitting element 120.

The encapsulation layer 117 may have a multilayer structure including a first encapsulation layer 117a, a second encapsulation layer 117b, and a third encapsulation layer 117c. However, the encapsulation layer may have a single layer structure. However, the present disclosure is not limited thereto.

The first encapsulation layer 117a and the third encapsulation layer 117c may be made of an inorganic material, and the second encapsulation layer 117b may be made of an organic material. The second encapsulation layer 117b may be thickest among the first encapsulation layer 117a, the second encapsulation layer 117b, and the third encapsulation layer 117c. The second encapsulation layer 117b may planarize an upper portion of the light-emitting element 120.

The first encapsulation layer 117a may be disposed on the cathode 123 and closest to the light-emitting element 120. The first encapsulation layer 117a may be made of an inorganic insulating material that may be deposited at a low temperature. For example, the first encapsulation layer 117a may be made of silicon nitride (SiNx), silicon oxide (SiOx), silicon oxynitride (SiON), aluminum oxide (Al₂O₃), or the like. However, the present disclosure is not limited thereto.

Meanwhile, because the first encapsulation layer 117a is deposited in a low-temperature ambience, it is possible to suppress damage to the light-emitting layer 122 made of an organic material vulnerable to a high-temperature ambience during a deposition process.

The second encapsulation layer 117b is disposed on the first encapsulation layer 117a. The second encapsulation layer 117b may be disposed to have a smaller area than the first encapsulation layer 117a. In this case, the second encapsulation layer 117b may be disposed to expose two opposite ends of the first encapsulation layer 117a. The second encapsulation layer 117b may serve as a buffer for mitigating stress between the layers caused when the display device 100 is bent. The second encapsulation layer 117b may serve to improve the planarization performance.

For example, the second encapsulation layer 117b may be made of an organic insulating material such as acrylic resin, epoxy resin, polyimide, polyethylene, or silicon oxycarbon (SiOC). For example, the second encapsulation layer 117b may also be formed in an inkjet manner. However, the present disclosure is not limited thereto.

The third encapsulation layer 117c may be formed above the substrate 110 having the second encapsulation layer 117b to cover a top surface and a side surface of each of the second encapsulation layer 117b and the first encapsulation layer 117a. In this case, the third encapsulation layer 117c may minimize or block the penetration of outside moisture or oxygen into the first encapsulation layer 117a and the second encapsulation layer 117b. For example, the third encapsulation layer 117c may be made of an inorganic insulating material such as silicon nitride (SiNx), silicon oxide (SiOx), silicon oxynitride (SiON), or aluminum oxide (Al₂O₃). However, the present disclosure is not limited thereto.

A touch detection layer is disposed on the encapsulation layer 117.

The touch detection layer may include the touch buffer layer 118a, the touch interlayer insulation layer 118b, and the touch electrode TE. The touch electrode TE may include a touch sensor metal TS and a bridge metal BM disposed on different layers.

For example, the touch buffer layer 118a may be disposed on the third encapsulation layer 117c, and the bridge metal BM may be disposed on the touch buffer layer 118a. The touch interlayer insulation layer 118b may be disposed on the bridge metal BM, and the touch sensor metal TS may be disposed on the touch interlayer insulation layer 118b.

For example, the touch buffer layer 118a and the touch interlayer insulation layer 118b may be made of an inorganic insulating material or an organic insulating material. Therefore, the touch buffer layer 118a and the touch interlayer insulation layer 118b may minimize a level difference at a point at which the touch electrode TE is disposed. The touch buffer layer 118a and the touch interlayer insulation layer 118b may electrically insulate the touch sensor metal TS and the bridge metal BM.

Meanwhile, although not illustrated in the drawings, a polarizing layer and a cover glass may be further disposed on the touch detection layer.

The polarizing layer suppresses the reflection of external light in the display area DA of the substrate 110. In case that the display device 100 is used outside, external natural light may be introduced and reflected by the reflective layer included in the anode 121 of the light-emitting element 120 or reflected by an electrode made of metal and disposed on a lower portion of the light-emitting element 120. The light beams, which are reflected as described above, may inhibit an image on the display device 100 from being visually recognized. The polarizing layer may polarize, in a particular direction, the light introduced from the outside, thereby inhibiting the reflected light from being discharged again to the outside of the display device 100.

The cover glass may be disposed on the polarizing layer. The cover glass may protect the constituent elements of the display device 100 from external impact and suppress damage such as scratches. The cover glass may be bonded to the polarizing layer by a bonding layer. The bonding layer may serve to bond the constituent elements of the display device 100. For example, the bonding layer may be formed by using a bonding agent for an optically transparent display such as a pressure-sensitive bonding agent, an optically transparent bonding agent (optical clear adhesive (OCR)), or an optically transparent resin (optical clear resin (OCR)). However, the present disclosure is not limited thereto.

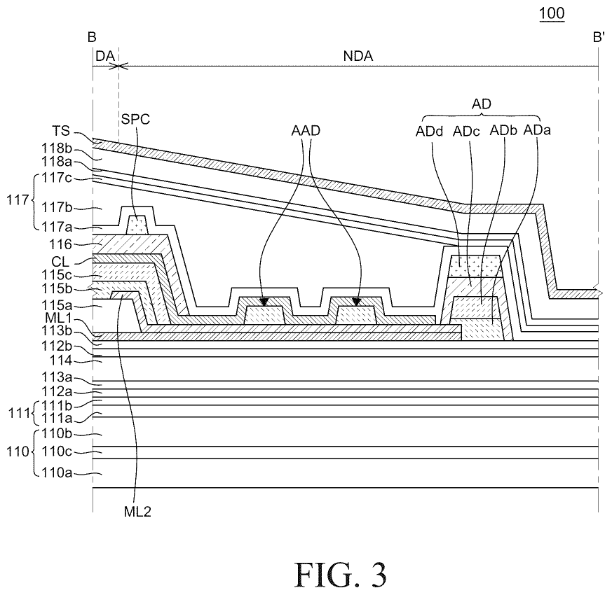

FIG. 3 is an example of a cross-sectional view taken along line B-B′ in FIG. 1A. FIG. 3 is an example of a cross-sectional view for explaining an outer periphery of the display area DA of the display device 100 and a cross-sectional structure of a part of the non-display area NDA according to the example embodiment of the present disclosure.

With reference to FIG. 3, a spacer SPC, an outer dam structure AD, and a plurality of auxiliary outer dams AAD are disposed in the non-display area NDA that surrounds the display area DA.

The spacer SPC may be disposed above the bank 116 in the non-display area NDA. The spacer SPC serves to maintain a predetermined gap so that a mask does not come into contact with the substrate during a process of manufacturing the light-emitting layer 122 made of an organic material.

Meanwhile, the drawings illustrate that the spacer SPC is disposed only in the non-display area NDA. However, the spacer SPC may also be disposed above the bank 116 corresponding to the area between the plurality of subpixels SP in the display area DA. In this case, the light-emitting layer 122 and the cathode 123 may be disposed on the spacer SPC disposed above the bank 116 in the display area DA. However, the present disclosure is not limited thereto.

For example, the spacer SPC may be made of an inorganic insulating material such as silicon nitride (SiNx) or silicon oxide (SiOx), or an organic insulating material such as benzocyclobutene-based resin, acrylic resin, or imide-based resin. However, the present disclosure is not limited thereto.

The outer dam structure AD may be disposed in the non-display area NDA and block a flow of the second encapsulation layer 117b made of an organic material, among the constituent elements that constitute the encapsulation layer 117. The outer dam structure AD may be disposed in the non-display area NDA and surround the entire outer periphery of the display area DA. Meanwhile, the outer dam structure AD may be provided as a plurality of outer dam structures AD, and the plurality of outer dam structures AD may be disposed to surround the outer periphery of the display area DA. However, the present disclosure is not limited thereto.

The outer dam structure AD may be disposed to surround the entire outer periphery of the display area DA while defining a closed loop shape. For example, in case that the outer dam structure AD, which is disposed to surround the outer periphery of the display area DA, is partially disconnected, the second encapsulation layer 117b may leak through the disconnected portion of the outer dam structure AD. Therefore, the outer dam structure AD may be disposed to surround the entire outer periphery of the display area DA while defining a closed loop shape.

The outer dam structure AD may have a multilayer structure having a predetermined height or more and made by stacking a plurality of organic material layers to block a flow of the second encapsulation layer 117b. For example, as illustrated in FIG. 3, the outer dam structure AD may include a first layer ADa formed of the same layer as the second planarization layer 115b, a second layer ADb formed of the same layer as the third planarization layer 115c, a third layer ADc formed of the same layer as the bank 116, and a fourth layer ADd formed of the same layer as the spacer SPC. In addition, the outer dam structure AD may further include a fifth layer formed of the same layer as the first planarization layer 115a. However, the present disclosure is not limited thereto.

Meanwhile, in the display device 100 according to the example embodiment of the present disclosure, the outer dam structure AD includes a plurality of layers formed of the same layers as the second planarization layer 115b and the third planarization layer 115c on which the anode having the side mirror structure is disposed. The outer dam structure AD includes a first layer ADa formed of the same layer as the second planarization layer 115b, and a second layer ADb formed of the same layer as the third planarization layer 115c. Therefore, in the outer dam structure AD, the third layer ADc, which is formed of the same layer as the bank 116, and the fourth layer ADd, which is formed of the same layer as the spacer SPC, may be disposed at higher positions. Therefore, in the display device 100 according to the example embodiment of the present disclosure, the outer dam structure AD may be configured to stably control a flow of the second encapsulation layer 117b even though a large level difference occurs between the display area DA and the non-display area NDA.

The plurality of auxiliary outer dams AAD is disposed inside the outer dam structure AD. The plurality of auxiliary outer dams AAD is disposed between the display area DA and the outer dam structure AD. The plurality of auxiliary outer dams AAD, together with the outer dam structure AD, may block a flow of the second encapsulation layer 117b. Therefore, for example, the plurality of auxiliary outer dams AAD may be referred to as stoppers. However, the present disclosure is not limited thereto. The plurality of auxiliary outer dams AAD may be disposed in the non-display area NDA and surround the entire outer periphery of the display area DA. For example, the plurality of auxiliary outer dams AAD may be disposed to surround the entire outer periphery of the display area DA while defining a closed loop shape.

For example, the plurality of auxiliary outer dams AAD may be formed of the same layer as the second planarization layer 115b and made of the same material as the second planarization layer 115b. For example, the plurality of auxiliary outer dams AAD may be made of an organic material such as acrylic resin, epoxy resin, phenolic resin, polyamide resin, and polyimide resin. However, the present disclosure is not limited thereto.

Meanwhile, with reference to FIG. 3, a first metal layer ML1, a second metal layer ML2, and a connection line CL are disposed in the non-display area NDA.

The first metal layer ML1 may be disposed on the second interlayer insulation layer 113b in the non-display area NDA. For example, the first metal layer ML1 may be a low-potential power line for transmitting a low-potential power voltage to the cathode 123. However, the present disclosure is not limited thereto.

The first metal layer ML1 may be disposed on the second interlayer insulation layer 113b and formed of the same layer as the first source electrode S1, the first drain electrode D1, the second source electrode S2, the second drain electrode D2, and the connection electrode CE. The second metal layer ML2 may be made of the same material as the first source electrode Si, the first drain electrode D1, the second source electrode S2, the second drain electrode D2, and the connection electrode CE. For example, the first metal layer ML1 may be configured as a single layer or multilayer made of any one of molybdenum (Mo), copper (Cu), titanium (Ti), aluminum (Al), chromium (Cr), gold (Au), nickel (Ni), and neodymium (Nd) or an alloy thereof. However, the present disclosure is not limited thereto.

The second metal layer ML2 may be disposed on the first metal layer ML1 and the first planarization layer 115a in the non-display area NDA. The second metal layer ML2 may be electrically connected to the first metal layer ML1 and disposed on the top surface of the first metal layer ML1 exposed from the first planarization layer 115a.

The second metal layer ML2 may be formed of the same layer as the auxiliary electrode AE and made of the same material as the auxiliary electrode AE. For example, the second metal layer ML2 may be configured as a single layer or multilayer made of any one of molybdenum (Mo), copper (Cu), titanium (Ti), aluminum (Al), chromium (Cr), gold (Au), nickel (Ni), and neodymium (Nd) or an alloy thereof. However, the present disclosure is not limited thereto.

The connection line CL may be disposed on the second metal layer ML2, the second planarization layer 115b, and the third planarization layer 115c in the non-display area NDA. The connection line CL may be electrically connected to the second metal layer ML2 and disposed on the second metal layer ML2 exposed from the second planarization layer 115b and the third planarization layer 115c.

The connection line CL may be formed of the same layer as the anode 121 and made of the same material as the anode 121. However, the connection line CL may be spaced apart from the anode 121 without being electrically connected to the anode 121, and the anode 121 and the connection line CL may serve as separate components. For example, the connection line CL may be configured as a single layer or multilayer including a metallic material. However, the present disclosure is not limited thereto.

Meanwhile, although not illustrated in the drawings, the connection line CL may be electrically connected to the cathode 123. For example, the bank 116 may be disposed on the connection line CL, and the cathode 123 may be electrically connected to the connection line CL through a contact hole formed in the bank 116. However, the present disclosure is not limited thereto. Therefore, the first metal layer ML1 may be electrically connected to the cathode 123 through the second metal layer ML2 and the connection line CL and transmit a low-potential power voltage to the cathode 123.

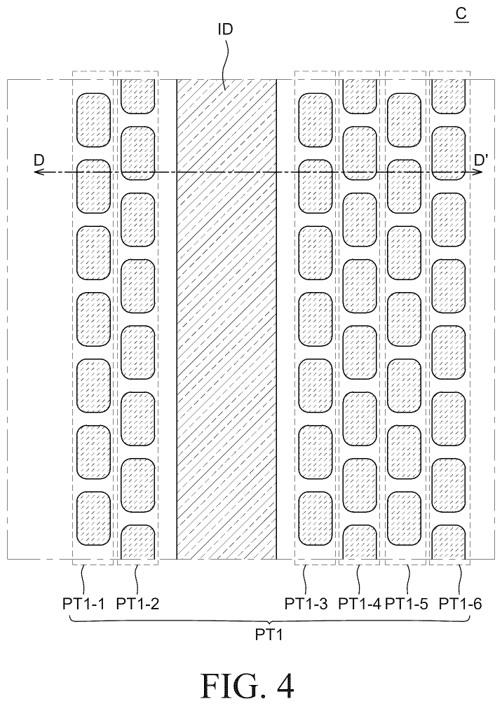

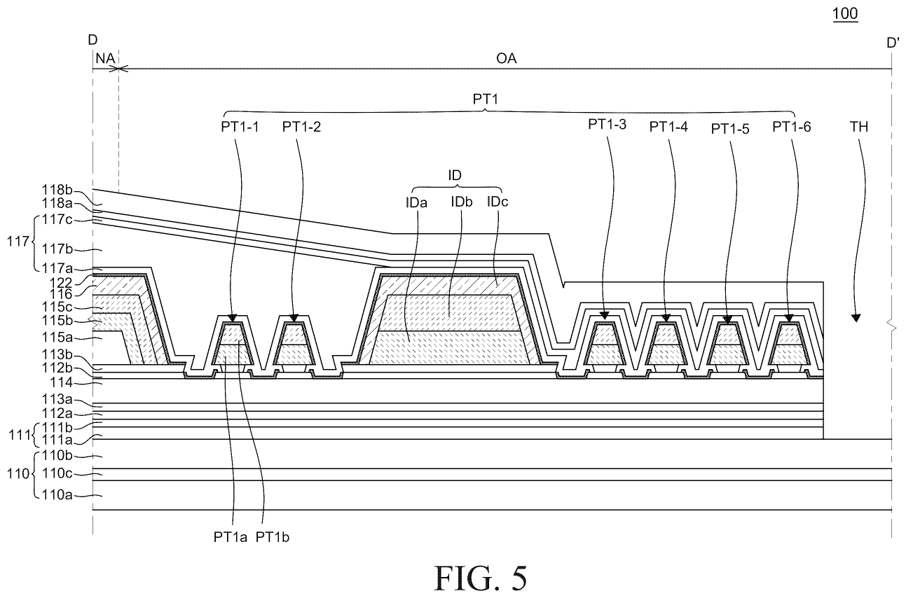

FIG. 4 is an example of an enlarged top plan view of area C in FIG. 1A. FIG. 5 is an example of a cross-sectional view taken along line D-D′ in FIG. 4. FIGS. 4 and 5 are examples of a top plan view and a cross-sectional view for explaining an inner dam structure ID and a plurality of first patterns PT1 disposed in the optical area OA of the display device 100 according to the example embodiment of the present disclosure. Meanwhile, for the convenience of description, FIG. 4 illustrates only the inner dam structure ID and the plurality of first patterns PT1.

With reference to FIGS. 1A and 5, the display area DA may include a normal display area NA and the optical area OA. In an example, the normal display area NA may be the display area DA excluding the optical area OA. In an example, the normal display area NA may be an area disposed within the display area DA but outside the optical area OA. An area may include one or more areas. A normal display area NA may include one or more normal display areas NA. An optical area OA may include one or more optical areas OA. When multiple optical areas OA are provided, a normal display area NA may be the display area DA excluding all optical areas OA. With reference to FIGS. 1A, 4, and 5, the inner dam structure ID and the plurality of first patterns PT1 are disposed between the normal display area NA and the through-hole TH in the optical area OA.

The inner dam structure ID is disposed in the optical area OA and surrounds the through-hole TH. The inner dam structure ID is disposed between the normal display area NA and the through-hole TH. The inner dam structure ID may be disposed in the optical area OA and block a flow of the second encapsulation layer 117b made of an organic material, among the constituent elements that constitute the encapsulation layer 117. Meanwhile, the inner dam structure ID may be provided as a plurality of inner dam structures ID, and the plurality of inner dam structures ID may be disposed to surround an outer periphery of the through-hole TH. However, the present disclosure is not limited thereto.

The inner dam structure ID may be disposed to surround the entire outer periphery of the through-hole TH while defining a closed loop shape. For example, in case that the inner dam structure ID, which is disposed to surround the outer periphery of the through-hole TH, is partially disconnected, the second encapsulation layer 117b may leak through the disconnected portion of the inner dam structure ID. Therefore, the inner dam structure ID may be disposed to surround the entire outer periphery of the through-hole TH while defining a closed loop shape.

The inner dam structure ID may have a multilayer structure having a predetermined height or more and made by stacking a plurality of organic material layers to block a flow of the second encapsulation layer 117b. For example, as illustrated in FIG. 5, the inner dam structure ID may include the first layer IDa formed of the same layer as the second planarization layer 115b, the second layer IDb formed of the same layer as the third planarization layer 115c, and a third layer IDc formed of the same layer as the bank 116. In addition, the inner dam structure ID may further include a fourth layer formed of the same layer as the first planarization layer 115a. However, the present disclosure is not limited thereto.

With reference to FIGS. 4 and 5, the plurality of first patterns PT1 is disposed along the inner dam structure ID. The plurality of first patterns PT1, together with the inner dam structure ID, may block a flow of the second encapsulation layer 117b.

Meanwhile, the plurality of first patterns PT1 may protect the light-emitting element 120 in the display area from moisture or oxygen that may be introduced from the through-hole TH. The light-emitting layer 122 of the light-emitting element 120 may be deposited on a front surface of the display panel DP and may also be uniformly deposited in the optical area OA. In this case, because of the nature of the organic material, the light-emitting layer 122 has high reactivity and dispersity in respect to moisture and oxygen, such that moisture and oxygen may be transmitted to the light-emitting element 120 in the display area DA. The plurality of first patterns PT1 may partially disconnect the light-emitting layer 122 to suppress the problem. Therefore, for example, the plurality of first patterns PT1 may be referred to as separators. However, the present disclosure is not limited thereto.

The plurality of first patterns PT1 includes a plurality of first-first patterns PT1-1, a plurality of first-second patterns PT1-2, a plurality of first-third patterns PT1-3, a plurality of first-fourth patterns PT1-4, a plurality of first-fifth patterns PT1-5, and a plurality of first-sixth patterns PT1-6. However, the number of patterns included in the plurality of first patterns PT1 is not limited thereto.

For example, the plurality of first patterns PT1 may be respectively disposed on a plurality of imaginary lines disposed to surround the inner dam structure ID. For example, the plurality of first-first patterns PT1-1, the plurality of first-second patterns PT1-2, the plurality of first-third patterns PT1-3, the plurality of first-fourth patterns PT1-4, the plurality of first-fifth patterns PT1-5, and the plurality of first-sixth patterns PT1-6 may be disposed on one line among the plurality of imaginary lines disposed to surround the inner dam structure ID. That is, the plurality of first-first patterns PT1-1, the plurality of first-second patterns PT1-2, the plurality of first-third patterns PT1-3, the plurality of first-fourth patterns PT1-4, the plurality of first-fifth patterns PT1-5, and the plurality of first-sixth patterns PT1-6 may be disposed to define an imaginary line disposed to surround the inner dam structure ID.

Meanwhile, with reference to FIGS. 4 and 5, the plurality of first patterns PT1 is disposed inside and outside the inner dam structure ID in the optical area OA. The plurality of first patterns PT1 may be disposed between the normal display area NA and the inner dam structure ID and between the through-hole TH and the inner dam structure ID. For example, among the plurality of first patterns PT1, the plurality of first-first patterns PT1-1 and the plurality of first-second patterns PT1-2 may be disposed between the normal display area NA and the inner dam structure ID, and the plurality of first-third patterns PT1-3, the plurality of first-fourth patterns PT1-4, the plurality of first-fifth patterns PT1-5, and the plurality of first-sixth patterns PT1-6 may be disposed between the through-hole TH and the inner dam structure ID. However, the present disclosure is not limited thereto.

Meanwhile, with reference to FIG. 5, the plurality of first patterns PT1 may each include a first layer PT1a and a second layer PT1b. For example, the first layer PT1a may be formed of the same layer as the second planarization layer 115b, and the second layer PT1b may be formed of the same layer as the third planarization layer 115c. In this case, the first layer PT1a and the second layer PT1b may have cross-sections with tapered shapes to disconnect the light-emitting layer 122 disposed above the first layer PT1a and the second layer PT1b. Further, an undercut structure may be formed below the side surface of the first layer PT1a to disconnect the light-emitting layer 122. Meanwhile, in order to form the undercut structure below the side surface of the first layer PT1a, the second gate insulation layer 112b and the second interlayer insulation layer 113b disposed on the plurality of first patterns PT1 may be partially removed by a process such as ashing, for example. However, the present disclosure is not limited thereto.

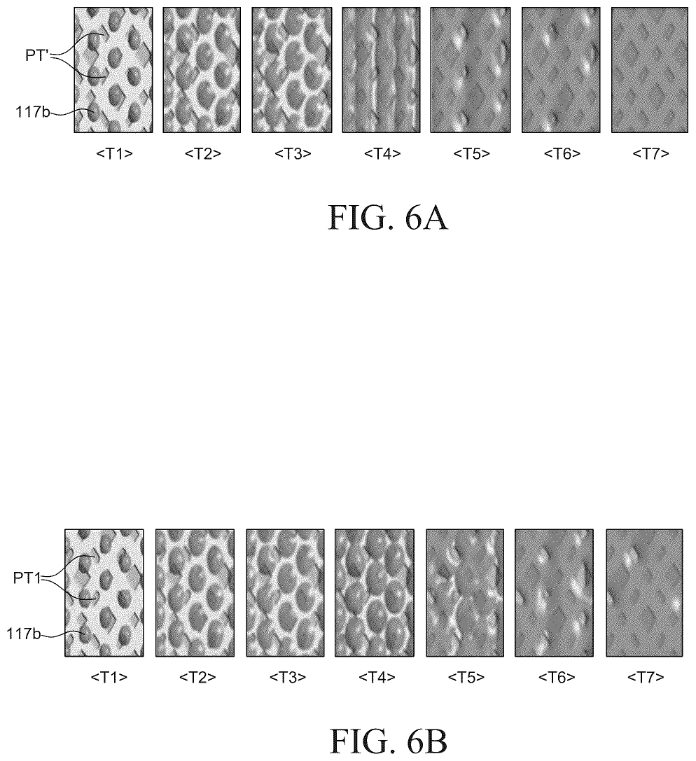

With reference to FIG. 4, the plurality of first patterns PT1 may be spaced apart from one another and have the same shape in a plan view. In one aspect, a plan view of the plurality of first patterns PT1 seen at the top of the second layer PT1b is illustrated in FIG. 4. A planar shape of each of the plurality of first patterns PT1 includes a curved line. For example, as illustrated in FIG. 4, the planar shape of each of the plurality of first patterns PT1 may be a rectangular shape with rounded corners. In this case, because the planar shape of each of the plurality of first patterns PT1 includes a curved line, the plurality of first patterns PT1 may be configured to hinder a flow of the second encapsulation layer 117b disposed above the plurality of first patterns PT1. However, a specific description thereof will be described below with reference to FIGS. 6A and 6B.

FIG. 6A is a view illustrating images showing, in temporal order, results of simulating a plurality of patterns and a second encapsulation layer of a display device according to a comparative example. FIG. 6B is a view illustrating images showing, in temporal order, results of simulating the plurality of patterns and the second encapsulation layer of the display device according to the example embodiment of the present disclosure. FIGS. 6A and 6B are views illustrating images showing the simulation of a process of filling a space, in which a plurality of patterns PT′ or the plurality of first patterns PT1 is disposed, with the second encapsulation layer 117b in accordance with a change in time of T1 to T7, i.e., a predetermined unit time. The simulations were performed on the display device according to the comparative example in FIG. 6A and the display device 100 according to the example embodiment of the present disclosure in FIG. 6B under a condition in which the remaining conditions, such as the materials of the plurality of patterns PT′ and the plurality of first patterns PT1, the material of the second encapsulation layer 117b, and the simulation process time, remain the same, and only the shapes of the plurality of patterns PT′ and the plurality of first patterns PT1 are different.

With reference to FIG. 6A, the display device according to the comparative example includes the plurality of patterns PT′. A planar shape of each of the plurality of patterns PT′ does not include a curved line. For example, the planar shape of each of the plurality of patterns PT′ may be a rectangular shape. It can be seen from FIG. 6A that the portions between the plurality of patterns PT′ are filled with the second encapsulation layer 117b in accordance with the change in time of T1 to T7. When the time of T7 is reached, the portions between the plurality of patterns PT′ and the upper portions of the plurality of patterns PT′ are filled with the second encapsulation layer 117b.

With reference to FIG. 6B, the planar shape of each of the plurality of first patterns PT1 includes a curved line. For example, the planar shape of each of the plurality of first patterns PT1 may be a rectangular shape with rounded corners. In FIG. 6B, the portions between the plurality of first patterns PT1 are filled with the second encapsulation layer 117b in accordance with the change in time of T1 to T7. In this case, it can be seen that a part of the portion between the plurality of first patterns PT1 and a part of the upper portion of the plurality of first patterns PT1 cannot be filled with the second encapsulation layer 117b even though the time of T7 is reached.

Therefore, with reference to FIGS. 6A and 6B, it can be seen that a rate at which the second encapsulation layer 117b is disposed in the display device according to the comparative example in which the plurality of patterns PT′ is disposed is higher than a rate at which the second encapsulation layer 117b is disposed in the display device 100 according to the example embodiment of the present disclosure in which the plurality of first patterns PT1 is disposed.

Meanwhile, the above-mentioned difference between the rates at which the second encapsulation layer 117b is disposed may occur as a capillarity phenomenon occurs between the plurality of rectangular patterns PT′ in the display device according to the comparative example in which the planar shape does not include a curved line, and the second encapsulation layer 117b is quickly moved between the plurality of patterns PT′ by the capillarity phenomenon.

In contrast, because the edge of the planar shape of each of the plurality of first patterns PT1, which includes a curved line, has a rounded rectangular shape, the occurrence of the capillarity phenomenon between the plurality of first patterns PT1 may be minimized, and the portions between the plurality of first patterns PT1 may be relatively slowly filled with the second encapsulation layer 117b. Therefore, the plurality of first patterns PT1 may be configured to decrease the movement speed of the second encapsulation layer 117b and hinder a flow of the second encapsulation layer 117b.

In the display device that uses the anode disposed on the planarization layer having the shape with the flat top surface, there is a problem in that the luminous efficiency deteriorates because the light beams, which are emitted at a small emergent angle among the light beams emitted from the light-emitting layer, are lost by being trapped in the display device because of a total reflection loss or a light wave loss. Therefore, the third planarization layer, which exposes the second planarization layer, is disposed, and the anode is disposed on the inclined side surface of the third planarization layer, and the side mirror structure is formed, such that the light emitted from light-emitting layer may be reflected and extracted to the outside of display device, which may improve the light extraction efficiency.

However, in the display device in which both the second planarization layer and the third planarization layer are disposed as described above, there may occur a very large level difference between the display area, in which the second planarization layer and the third planarization layer are disposed, and the optical area in which the second planarization layer and the third planarization layer are not disposed. Therefore, a large amount of the second encapsulation layer needs to be disposed so that the second encapsulation layer, which is the organic material layer that partially covers the display area and the optical area, may smoothly planarize the upper portion of the light-emitting element or the like, for example.

However, in case that the amount of the disposed second encapsulation layer increases, there may occur a problem in that the second encapsulation layer enters the through-hole beyond the inner dam structure configured to include the second planarization layer, for example, while surrounding the through-hole in the optical area.

In the display device 100 according to the example embodiment of the present disclosure, the inner dam structure ID includes the first layer IDa and the second layer IDb, such that the inner dam structure ID may be configured to stably control a flow of the second encapsulation layer 117b.

Specifically, the anode 121 may be disposed on the top surface of the second planarization layer 115b and the side surface of the third planarization layer 115c and configured to have a side mirror structure. Therefore, the anode 121 disposed on an inclined side surface of the third planarization layer 115c may reflect the light emitted from the light-emitting layer 122 and extract the light to the outside of the display device 100, thereby improving the light extraction efficiency of the light-emitting element 120. Further, the inner dam structure ID includes the first layer IDa formed of the same layer as the second planarization layer 115b, and the second layer IDb formed of the same layer as the third planarization layer 115c. That is, in the inner dam structure ID of the display device 100 according to the example embodiment of the present disclosure, the second layer IDb, which is formed of the same layer as the third planarization layer 115c, may be further disposed, in comparison with a display device in which the anode having the side mirror structure is not disposed. Therefore, even though a large level difference occurs between the normal display area NA and the optical area OA, the inner dam structure ID may be configured to stably control a flow of the second encapsulation layer 117b.

Meanwhile, a separate process of forming the first layer IDa and the second layer IDb may not be added because the first layer IDa of the inner dam structure ID is formed of the same layer as the second planarization layer 115b, and the second layer IDb is formed of the same layer as the third planarization layer 115c in the display device 100 according to the example embodiment of the present disclosure. Therefore, there is an additional advantage capable of simplifying the process of manufacturing the display device 100 in the display device 100 according to the example embodiment of the present disclosure.

In the display device 100 according to the example embodiment of the present disclosure, the planar shape of each of the plurality of first patterns PT1 includes a curved line, and a flow of the second encapsulation layer 117b is minimized, such that an arrangement area of the plurality of first patterns PT1 may be minimized.

Specifically, because the edge of the planar shape of each of the plurality of first patterns PT1, which includes a curved line, has a rounded rectangular shape, the occurrence of the capillarity phenomenon between the plurality of first patterns PT1 may be minimized, and the portions between the plurality of first patterns PT1 may be relatively slowly filled with the second encapsulation layer 117b. Therefore, the plurality of first patterns PT1 may be configured to decrease the movement speed of the second encapsulation layer 117b and minimize a flow of the second encapsulation layer 117b. Therefore, even though the plurality of first patterns PT1 is disposed in a smaller area in comparison with the case in which the planar shape does not include a curved line, a flow of the second encapsulation layer 117b may be minimized. Therefore, in the display device 100 according to the example embodiment of the present disclosure, the planar shape of each of the plurality of first patterns PT1 includes a curved line, and a flow of the second encapsulation layer 117b is minimized, such that an arrangement area of the plurality of first patterns PT1 may be minimized. Further, it is possible to implement the display device 100 with a narrow bezel because a size of a bezel area is minimized in the same area.

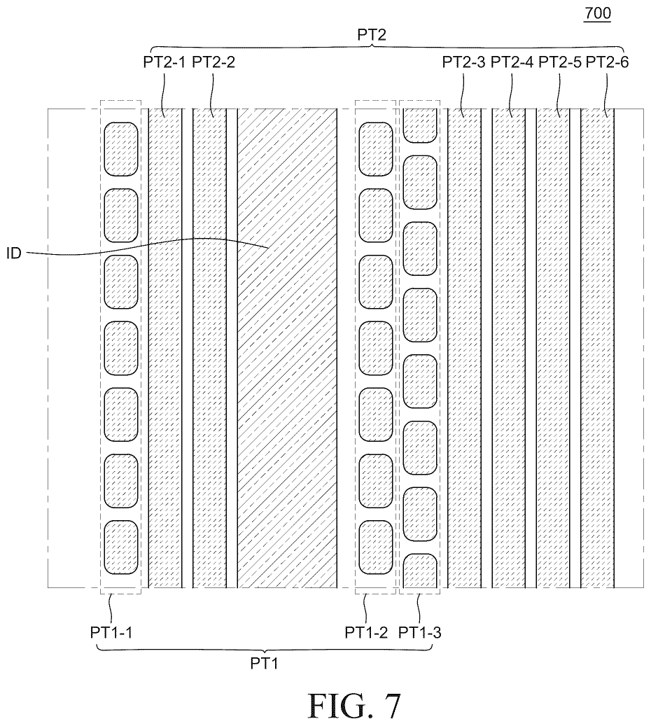

FIG. 7 is an enlarged top plan view of a display device according to another example embodiment of the present disclosure. A display device 700 in FIG. 7 is substantially identical in configuration to the display device 100 in FIGS. 1A to 5 and 6B, except for a plurality of second patterns PT2. Therefore, repeated descriptions of the identical components will be omitted. Meanwhile, for the convenience of description, FIG. 7 illustrates only the inner dam structure ID, the plurality of first patterns PT1, and the plurality of second patterns PT2.

With reference to FIG. 7, the plurality of second patterns PT2 is disposed between the inner dam structure ID and the plurality of first patterns PT1. The plurality of second patterns PT2 is disposed between the inner dam structure ID and the plurality of first patterns PT1 and surrounds the through-hole TH. For example, the plurality of second patterns PT2 may be disposed to surround the entire outer periphery of the through-hole TH while defining a closed loop shape. Meanwhile, the plurality of second patterns PT2 may have the same cross-sectional structure as the plurality of first patterns PT1. For example, the plurality of second patterns PT2 may each include a first layer formed of the same layer as the second planarization layer 115b, and a second layer formed of the same layer as the third planarization layer 115c. In one aspect, a plan view of the plurality of first patterns PT1 and the plurality of second patterns PT2 seen at the top of the second layer is illustrated in FIG. 7.

The plurality of second patterns PT2 may include a second-first pattern PT2-1, a second-second pattern PT2-2, a second-third pattern PT2-3, a second-fourth pattern PT2-4, a second-fifth pattern PT2-5, and a second-sixth pattern PT2-6. For example, the second-first pattern PT2-1 and the second-second pattern PT2-2 may be disposed between the inner dam structure ID and the first-first pattern PT1-1, and the second-third pattern PT2-3, the second-fourth pattern PT2-4, the second-fifth pattern PT2-5, and the second-sixth pattern PT2-6 may be disposed between the first-second pattern PT1-3 and the through-hole TH. However, the arrangement order of the plurality of first patterns PT and the plurality of second patterns PT2, the number of first patterns PT, and the number of second patterns PT2 are not limited thereto.

In the display device 700 according to another example embodiment of the present disclosure, the planar shape of each of the plurality of first patterns PT1 includes a curved line, and a flow of the second encapsulation layer 117b is minimized, such that an arrangement area of the plurality of first patterns PT1 may be minimized.

Specifically, because the edge of the planar shape of each of the plurality of first patterns PT1, which includes a curved line, has a rounded rectangular shape, the occurrence of the capillarity phenomenon between the plurality of first patterns PT1 may be minimized, and the portions between the plurality of first patterns PT1 may be relatively slowly filled with the second encapsulation layer 117b. Therefore, the plurality of first patterns PT1 may be configured to decrease the movement speed of the second encapsulation layer 117b and minimize a flow of the second encapsulation layer 117b. Therefore, even though the plurality of first patterns PT1 is disposed in a smaller area in comparison with the case in which the planar shape does not include a curved line, a flow of the second encapsulation layer 117b may be minimized. Therefore, in the display device 700 according to another example embodiment of the present disclosure, the planar shape of each of the plurality of first patterns PT1 includes a curved line, and a flow of the second encapsulation layer 117b is minimized, such that an arrangement area of the plurality of first patterns PT1 may be minimized. Further, it is possible to implement the display device 700 with a narrow bezel because a size of a bezel area is minimized in the same area.

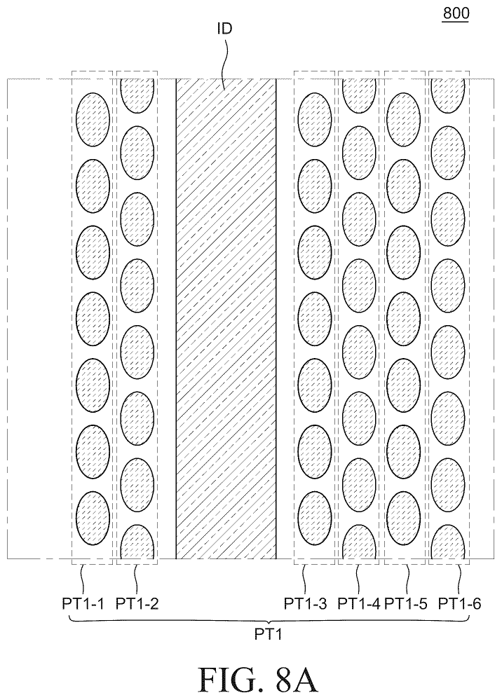

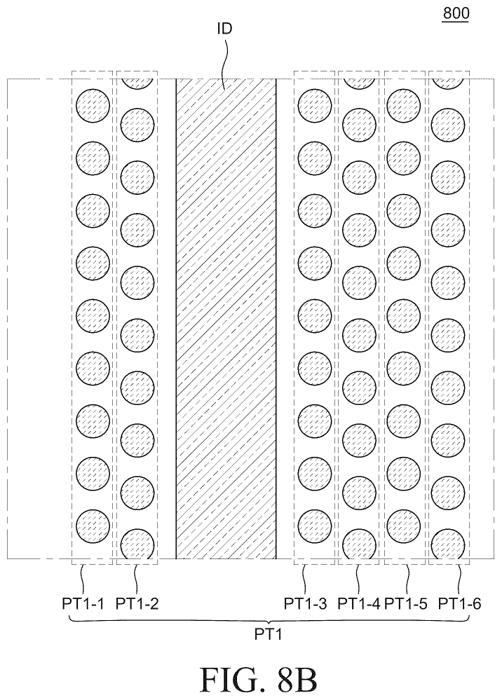

FIGS. 8A and 8B are enlarged top plan views of a display device according to still another example embodiment of the present disclosure. A display device 800 in FIGS. 8A and 8B is substantially identical in configuration to the display device 100 in FIGS. 1A to 5 and 6B, except for shapes of the plurality of first patterns PT1. Therefore, repeated descriptions of the identical components will be omitted. Meanwhile, for the convenience of description, FIGS. 8A and 8B illustrate only the inner dam structure ID and the plurality of first patterns PT1.

With reference to FIGS. 8A and 8B, the planar shape of each of the plurality of first patterns PT1 may include a curved line without including a straight line. For example, the planar shape of each of the plurality of first patterns PT1 may be a circular or elliptical shape. However, the present disclosure is not limited thereto.

As the number of curved lines included in the planar shape of each of the plurality of first patterns PT1 increases, the capillarity phenomenon occurring on the second encapsulation layer 117b disposed above the plurality of first patterns PT1 may be further minimized. Therefore, for example, in case that the planar shape of each of the plurality of first patterns PT1 is a circular or elliptical shape including no straight line, a flow of the second encapsulation layer 117b may be minimized.

In the display device 800 according to still another example embodiment of the present disclosure, the planar shape of each of the plurality of first patterns PT1 is a circular or elliptical shape, and a flow of the second encapsulation layer 117b is further minimized, such that an arrangement area of the plurality of first patterns PT1 may be minimized.

Specifically, because the planar shape of each of the plurality of first patterns PT1 is a circular or elliptical shape including no straight line, the occurrence of the capillarity phenomenon between the plurality of first patterns PT1 may be further minimized, and the portions between the plurality of first patterns PT1 may be further relatively slowly filled with the second encapsulation layer 117b. Therefore, the plurality of first patterns PT1 may be configured to further decrease the movement speed of the second encapsulation layer 117b and further minimize a flow of the second encapsulation layer 117b. Therefore, even though the plurality of first patterns PT1 is disposed in a smaller area in comparison with the case in which the planar shape includes a straight line, a flow of the second encapsulation layer 117b may be minimized. Therefore, in the display device 800 according to still another example embodiment of the present disclosure, the planar shape of each of the plurality of first patterns PT1 is a circular or elliptical shape including no straight line, and a flow of the second encapsulation layer 117b is further minimized, such that an arrangement area of the plurality of first patterns PT1 may be further minimized. Further, it is possible to implement the display device 800 with a narrow bezel because a size of a bezel area is further minimized in the same area.

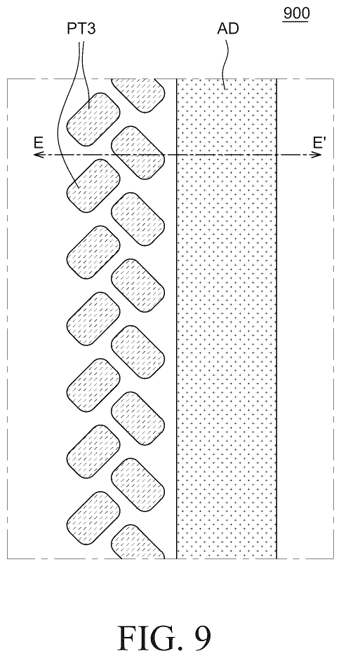

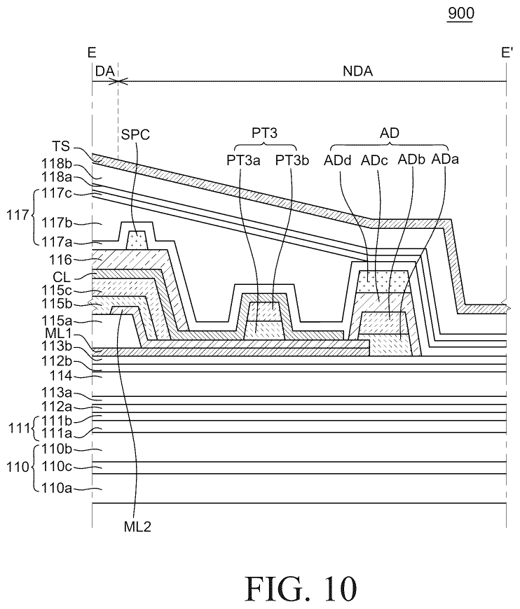

FIG. 9 is an enlarged top plan view of a display device according to yet another example embodiment of the present disclosure. FIG. 10 is an example of a cross-sectional view taken along line E-E′ in FIG. 9. A display device 900 in FIGS. 9 and 10 is substantially identical in configuration to the display device 100 in FIGS. 1A to 5 and 6B, except that a plurality of third patterns PT3 is disposed. Therefore, repeated descriptions of the identical components will be omitted. Meanwhile, for the convenience of description, FIG. 9 illustrates only the outer dam structure AD and the plurality of third patterns PT3.

With reference to FIG. 10, the outer dam structure AD may include the first layer ADa formed of the same layer as the second planarization layer 115b, the second layer ADb formed of the same layer as the third planarization layer 115c, the third layer ADc formed of the same layer as the bank 116, and the fourth layer ADd formed of the same layer as the spacer SPC. In addition, the outer dam structure AD may further include the fifth layer formed of the same layer as the first planarization layer 115a. However, the present disclosure is not limited thereto.

With reference to FIGS. 9 and 10, the plurality of third patterns PT3 is disposed inside the outer dam structure AD. The plurality of third patterns PT3 is disposed between the display area DA and the outer dam structure AD. For example, the plurality of third patterns PT3 may be disposed along a plurality of imaginary lines disposed to surround the outer dam structure AD. The plurality of third patterns PT3, together with the outer dam structure AD, may block a flow of the second encapsulation layer 117b. Therefore, for example, the plurality of third patterns PT3 may be referred to as stoppers. However, the present disclosure is not limited thereto.

Meanwhile, with reference to FIG. 10, the plurality of third patterns PT3 may each include a first layer PT3a and a second layer PT3b. The plurality of third patterns PT3 may each include a plurality of layers formed of the same layers as the second planarization layer 115b and the third planarization layer 115c on which the anode 121 having the side mirror structure is disposed. For example, the first layer PT3a may be formed of the same layer as the second planarization layer 115b, and the second layer PT3b may be formed of the same layer as the third planarization layer 115c. However, the plurality of third patterns PT3 may further include the third layer in addition to the first layer PT3a and the second layer PT3b. However, the number of layers included in each of the plurality of third patterns PT3 is not limited thereto.

Meanwhile, the plurality of third patterns PT3 may include the plurality of layers and thus have a higher height in comparison with a case in which the plurality of third patterns is disposed as a single layer. Therefore, the plurality of third patterns PT3 may be configured to more stably control a flow of the second encapsulation layer 117b. In addition, because the area in which the plurality of third patterns PT3 is disposed may be minimized, a size of the bezel area in the same area may be minimized.

With reference to FIG. 9, the plurality of third patterns PT3 may be spaced apart from one another and have the same shape in a plan view. A planar shape of each of the plurality of third patterns PT3 includes a curved line. For example, as illustrated in FIG. 9, the planar shape of each of the plurality of third patterns PT3 may be a rectangular shape with rounded corners. In this case, because the planar shape of each of the plurality of third patterns PT3 includes a curved line, the plurality of third patterns PT3 may be configured to hinder a flow of the second encapsulation layer 117b disposed above the plurality of third patterns PT3.

In the display device 900 according to yet another example embodiment of the present disclosure, the outer dam structure AD includes the first layer ADa and the second layer ADb, such that the outer dam structure AD may be configured to stably control a flow of the second encapsulation layer 117b.

Specifically, the anode 121 may be disposed on the top surface of the second planarization layer 115b and the side surface of the third planarization layer 115c and configured to have a side mirror structure. Therefore, the anode 121 disposed on an inclined side surface of the third planarization layer 115c may reflect the light emitted from the light-emitting layer 122 and extract the light to the outside of the display device 900, thereby improving the light extraction efficiency of the light-emitting element 120. Further, the outer dam structure AD includes the first layer ADa formed of the same layer as the second planarization layer 115b, and the second layer ADb formed of the same layer as the third planarization layer 115c. That is, in the outer dam structure AD of the display device 900 according to yet another example embodiment of the present disclosure, the second layer ADb, which is formed of the same layer as the third planarization layer 115c, may be further disposed, in comparison with a display device in which the anode having the side mirror structure is not disposed. Therefore, in the outer dam structure AD, the third layer ADc, which is formed of the same layer as the bank 116, and the fourth layer ADd, which is formed of the same layer as the spacer SPC, may be disposed at higher positions. Therefore, even though a large level difference occurs between the display area DA and the non-display area NDA, the outer dam structure AD may be configured to stably control a flow of the second encapsulation layer 117b.

In the display device 900 according to yet another example embodiment of the present disclosure, the planar shape of each of the plurality of third patterns PT3 includes a curved line, and a flow of the second encapsulation layer 117b is minimized, such that an arrangement area of the plurality of third patterns PT3 may be minimized.

Specifically, because the edge of the planar shape of each of the plurality of third patterns PT3, which includes a curved line, has a rounded rectangular shape, the occurrence of the capillarity phenomenon between the plurality of third patterns PT3 may be minimized, and the portions between the plurality of third patterns PT3 may be relatively slowly filled with the second encapsulation layer 117b. Therefore, the plurality of third patterns PT3 may be configured to decrease the movement speed of the second encapsulation layer 117b and minimize a flow of the second encapsulation layer 117b. Therefore, even though the plurality of third patterns PT3 is disposed in a smaller area in comparison with the case in which the planar shape does not include a curved line, a flow of the second encapsulation layer 117b may be minimized. Therefore, in the display device 900 according to yet another example embodiment of the present disclosure, the planar shape of each of the plurality of third patterns PT3 includes a curved line, and a flow of the second encapsulation layer 117b is minimized, such that an arrangement area of the plurality of third patterns PT3 may be minimized. Further, it is possible to implement the display device 900 with a narrow bezel because a size of a bezel area is minimized in the same area.

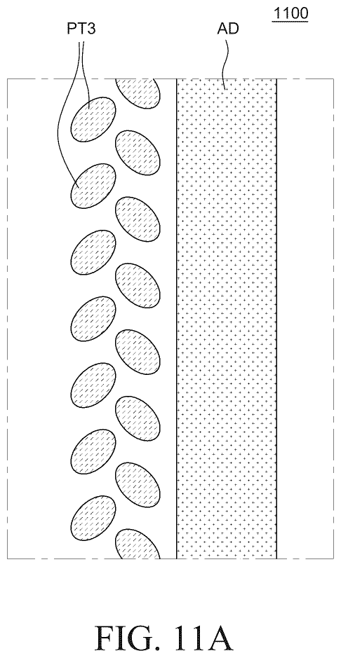

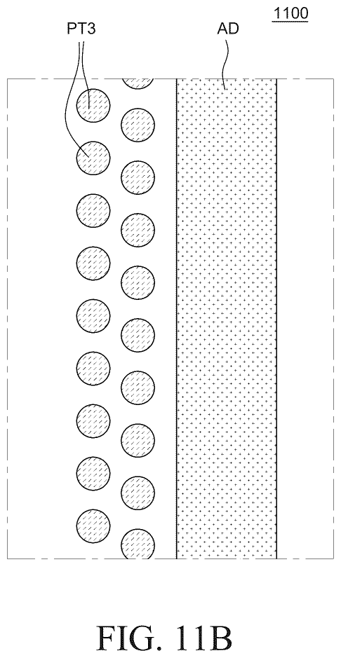

FIGS. 11A and 11B are enlarged top plan views of a display device according to still yet another example embodiment of the present disclosure. A display device 1100 in FIGS. 4, 11A, and 11B is substantially identical in configuration to the display device 900 in FIGS. 9 and 10, except for shapes of the plurality of third patterns PT3. Therefore, repeated descriptions of the identical components will be omitted. Meanwhile, for the convenience of description, FIGS. 11A and 11B illustrate only the outer dam structure AD and the plurality of third patterns PT3.

With reference to FIGS. 11A and 11B, the planar shape of each of the plurality of third patterns PT3 may include a curved line without including a straight line. For example, the planar shape of each of the plurality of third patterns PT3 may be a circular or elliptical shape. However, the present disclosure is not limited thereto.

As the number of curved lines included in the planar shape of each of the plurality of third patterns PT3 increases, the capillarity phenomenon occurring on the second encapsulation layer 117b disposed above the plurality of third patterns PT3 may be further minimized. Therefore, for example, in case that the planar shape of each of the plurality of third patterns PT3 is a circular or elliptical shape including no straight line, a flow of the second encapsulation layer 117b may be minimized.

In the display device 1100 according to still yet another example embodiment of the present disclosure, the planar shape of each of the plurality of third patterns PT3 is a circular or elliptical shape, and a flow of the second encapsulation layer 117b is further minimized, such that an arrangement area of the plurality of third patterns PT3 may be minimized.

Specifically, because the planar shape of each of the plurality of third patterns PT3 is a circular or elliptical shape including no straight line, the occurrence of the capillarity phenomenon between the plurality of third patterns PT3 may be further minimized, and the portions between the plurality of third patterns PT3 may be further relatively slowly filled with the second encapsulation layer 117b. Therefore, the plurality of third patterns PT3 may be configured to further decrease the movement speed of the second encapsulation layer 117b and further minimize a flow of the second encapsulation layer 117b. Therefore, even though the plurality of third patterns PT3 is disposed in a smaller area in comparison with the case in which the planar shape includes a straight line, a flow of the second encapsulation layer 117b may be minimized. Therefore, in the display device 1100 according to still another example embodiment of the present disclosure, the planar shape of each of the plurality of third patterns PT3 is a circular or elliptical shape including no straight line, and a flow of the second encapsulation layer 117b is further minimized, such that an arrangement area of the plurality of third patterns PT3 may be further minimized. Further, it is possible to implement the display device 1100 with a narrow bezel because a size of a bezel area is further minimized in the same area.

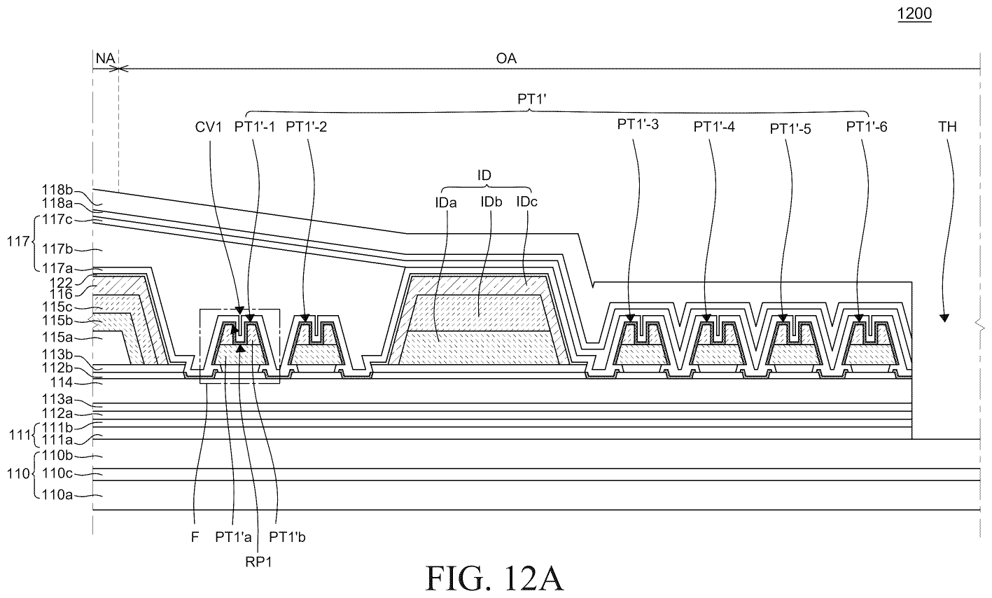

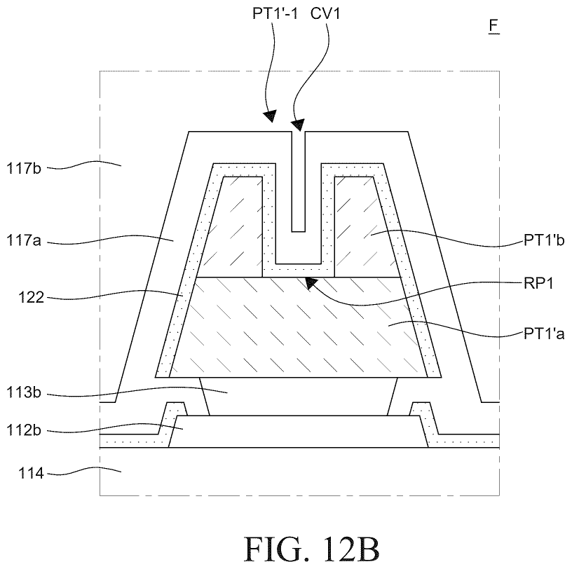

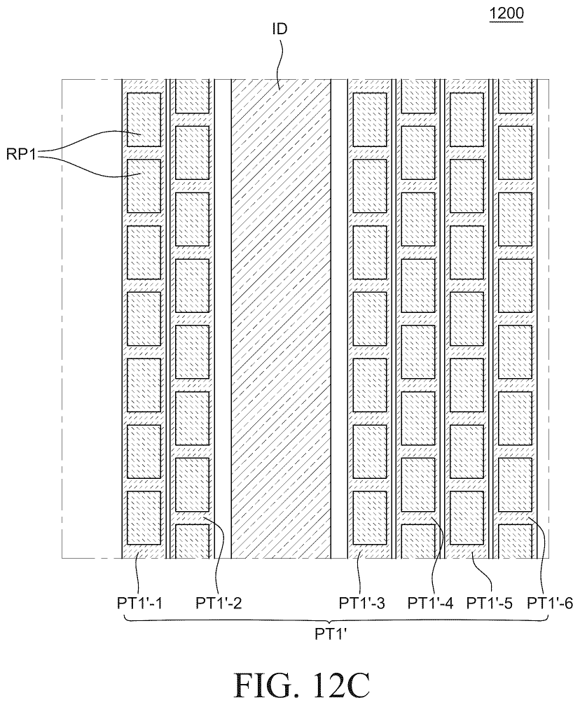

FIG. 12A is an example of a cross-sectional view of area C in FIG. 1A. FIG. 12B is an example of an enlarged view of area F in FIG. 12A. FIG. 12C is another example of an enlarged top plan view of area C in FIG. 1A.

A display device 1200 in FIGS. 12A to 12C is, or may be, substantially identical in configuration to the display device in FIGS. 1A to 5 and 6B to 11B (in particular FIGS. 4 and 5), except for a plurality of reshaped patterns PT1′. Therefore, repeated descriptions of the identical or substantially identical components will be omitted. Meanwhile, for the convenience of description, FIG. 12A is substantially identical to FIG. 5, except that the plurality of first patterns PT1 of FIG. 5 is replaced by the plurality of reshaped patterns PT1′ of FIG. 12A. Further, FIG. 12C is substantially identical to FIG. 4, except that the plurality of first patterns PT1 of FIG. 4 is replaced by the plurality of reshaped patterns PT1′ of FIG. 12A. In one or more other examples, a display device may include one or more reshaped patterns PT1′, one or more first patterns PT1, or some combination thereof.

With reference to FIGS. 1A and 12A, the display area DA may include the normal display area NA and the optical area OA. In an example, the normal display area NA may be the display area DA excluding the optical area OA. In an example, the normal display area NA may be an area disposed within the display area DA but outside the optical area OA. An area may be one or more areas. With reference to FIGS. 1A, 12A and 12C, the inner dam structure ID and the plurality of reshaped patterns PT1′ may be disposed between the normal display area NA and the through-hole TH in the optical area OA.

With reference to FIGS. 12A and 12C, the plurality of reshaped patterns PT1′ is disposed along the inner dam structure ID. The plurality of reshaped patterns PT1′, together with the inner dam structure ID, may block a flow of the second encapsulation layer 117b.

Meanwhile, the plurality of reshaped patterns PT1′ may protect the light-emitting elements 120 in the display area from moisture or oxygen that may be introduced from the through-hole TH. The light-emitting layer 122 of the light-emitting elements 120 may be deposited on a front surface of the display panel DP and may also be uniformly deposited in the optical area OA. In this case, because of the nature of the organic material, the light-emitting layer 122 has high reactivity and dispersity in respect to moisture and oxygen, such that moisture and oxygen may be transmitted to the light-emitting elements 120 in the display area DA. The plurality of reshaped patterns PT1′ may partially disconnect the light-emitting layer 122 to suppress the problem. Therefore, for example, the plurality of reshaped patterns PT1′ may be referred to as separators. However, the present disclosure is not limited thereto.

The plurality of reshaped patterns PT1′ includes a reshaped-first pattern PT1′-1, a reshaped-second pattern PT1′-2, a reshaped-third pattern PT1′-3, a reshaped-fourth pattern PT1′-4, a reshaped-fifth pattern PT1′-5, and a reshaped-sixth pattern PT1′-6. However, the number of patterns included in the plurality of reshaped patterns PT1′ is not limited thereto.

For example, the plurality of reshaped patterns PT1′ may be respectively disposed on a plurality of imaginary lines disposed to surround the inner dam structure ID. For example, the reshaped-first pattern PT1′-1, the reshaped-second pattern PT1′-2, reshaped-third pattern PT1′-3, the reshaped-fourth pattern PT1′-4, the reshaped-fifth pattern PT1′-5, and the reshaped-sixth pattern PT1′-6 may be disposed on one line among the plurality of imaginary lines disposed to surround the inner dam structure ID. That is, the reshaped-first pattern PT1′-1, the reshaped-second pattern PT1′-2, reshaped-third pattern PT1′-3, the reshaped-fourth pattern PT1′-4, the reshaped-fifth pattern PT1′-5, and the reshaped-sixth pattern PT1′-6 may be disposed to define an imaginary line disposed to surround the inner dam structure ID.

Meanwhile, with reference to FIGS. 12A and 12C, the plurality of reshaped patterns PT1′ is disposed inside and outside the inner dam structure ID in the optical area OA. The plurality of reshaped patterns PT1′ may be disposed between the normal display area NA and the inner dam structure ID and between the through-hole TH and the inner dam structure ID. For example, among the plurality of reshaped patterns PT1′, the reshaped-first pattern PT1′-1 and the reshaped-second pattern PT1′-2 may be disposed between the normal display area NA and the inner dam structure ID, and reshaped-third pattern PT1′-3, the reshaped-fourth pattern PT1′-4, the reshaped-fifth pattern PT1′-5, and the reshaped-sixth pattern PT1′-6 may be disposed between the through-hole TH and the inner dam structure ID. However, the present disclosure is not limited thereto.

With reference to FIG. 12C, the plurality of reshaped patterns PT1′ may be spaced apart from one another and have the same shape in a plan view.

Meanwhile, with reference to FIGS. 12A to 12C, the plurality of reshaped patterns PT1′ may each include a first layer PT1′a and a second layer PT1′b. For example, the first layer PT1′a may be formed of the same layer as the second planarization layer 115b, and the second layer PT1′b may be formed of the same layer as the third planarization layer 115c. In this case, the first layer PT1′a and the second layer PT1′b may have cross-sections with tapered shapes to disconnect the light-emitting layer 122 disposed above the first layer PT1′a and the second layer PT1′b. Further, an undercut structure may be formed below the side surface of the first layer PT1′a to disconnect the light-emitting layer 122. Meanwhile, in order to form the undercut structure below the side surface of the first layer PT1′a, the second gate insulation layer 112b and the second interlayer insulation layer 113b disposed on the plurality of reshaped patterns PT1′ may be partially removed by a process such as ashing, for example. However, the present disclosure is not limited thereto. In one aspect, a plan view of the plurality of reshaped patterns PT1′ seen at the first and second layers PT1′a and PT1′b is illustrated in FIG. 12C.

Each reshaped pattern (e.g., PT1′-1, PT1′-2, PT1′-3, PT1′-4, PT1′-5, or PT1′-6) may include recessed portions RP1. For example, with reference to FIG. 12C, the reshaped-first pattern PT1′-1 is shown with seven recessed portions disposed along the length direction of the reshaped-first pattern PT1′-1.

With reference to FIGS. 12B and 12C, each recessed portion RP1 may be formed in the second layer PT1′b. For example, the height of each recessed portion RP1 may be identical to the height of the second layer PT1′b. For example, each recessed portion RP1 may be, or may include, an opening in the second layer PT1′b, where the opening begins from the top of the second layer PT1′b and ends at the bottom of the second layer PT1′b.

The light-emitting layer 122 may be disposed on the side surfaces of the first layer PT1′a and the side surfaces and the top surface of the second layer PT1′b. The light-emitting layer 122 may be also disposed in each recessed portion RP1. For example, the light-emitting layer 122 may cover the side surfaces of each recessed portion RP1 and a bottom of each recessed portion RP1 (i.e., a top surface of the first layer PT1′a that is exposed by each respective recessed portion RP1).

The first encapsulation layer 117a may be disposed on the outer side surfaces of the light-emitting layer 122 and the top surface of the light-emitting layer 122. The first encapsulation layer 117a may be also disposed in each recessed portion RP1. For example, the first encapsulation layer 117a may cover the inner side surfaces of the light-emitting layer 122 in each recessed portion RP1 and the lower top surface of the light-emitting layer 122 in each recessed portion RP1.

The second encapsulation layer 117b may cover the first encapsulation layer 117a. For example, the second encapsulation layer 117b may be disposed on the outer side surfaces of the first encapsulation layer 117a and the top surface of the first encapsulation layer 117a. The second encapsulation layer 117b may be also disposed in (or fill) each recessed portion RP1. For example, the second encapsulation layer 117b may cover the inner side surfaces of the first encapsulation layer 117a in each recessed portion RP1 and the lower top surface of the first encapsulation layer 117a in each recessed portion RP1. In another example, the second encapsulation layer 117b may fill at least a portion of each recessed portion RP1. In yet another example, the second encapsulation layer 117b may fill at least a portion of each of some recessed portions RP1. In yet another example, the second encapsulation layer 117b may fill up to the extended top of each recessed portion RP1 (e.g., fill the entire cavity CV1 or a portion of the cavity CV1 created by the first encapsulation layer 117a at each recessed portion RP1), where the extended top is formed by the light-emitting layer 122 and the first encapsulation layer 117a.

Thus, in one or more examples, the second encapsulation layer 117b may fill at least a portion of a recessed portion RP1, fill at least a portion of each recessed portion RP1, or fill at least a portion of each of some recessed portions RP1. In one or more examples, the second encapsulation layer 117b may fill at least a portion or an entirety of a cavity CV1 at a recessed portion RP1, fill at least a portion or an entirety of a cavity CV1 at each recessed portion RP1, or fill at least a portion or an entirety of a cavity CV1 at each of some recessed portions RP1.

Each recessed portion RP1 formed in the second layer PT1′b may have a polygonal shape in a plan view. A polygonal shape may be, for example, as a quadrangular shape (e.g., a square shape or a rectangle shape) or an octagonal shape.

Meanwhile, with reference to FIGS. 1B and 12C, the planar shape of each recessed portion RP1 may be identical to (or may correspond to) a planar shape of a light-emitting area of a green subpixel SPG. For example, the plurality of reshaped patterns PT1′ (or the recessed portions RP1) may be made by using a mask identical to a mask used for the anode 121 for forming an area corresponding to the light-emitting area of the green subpixel SPG during the manufacturing process. Therefore, the number of masks required to form the plurality of reshaped patterns PT1′ (or the recessed portions RP1) may be reduced. However, the present disclosure is not limited thereto.

In the display device 1200 according to the example embodiment of the present disclosure, the planar shape of each recessed portion RP1 of the plurality of reshaped patterns PT1′ is a polygonal shape. Because the second encapsulation layer 117b flows into the recessed portions RP1 (and/or the cavities CV1 corresponding to the recessed portions RP1), a flow of the second encapsulation layer 117b (from the normal display area NA to the through-hole TH) is minimized, such that an arrangement area of the plurality of reshaped patterns PT1′ may be minimized.

Specifically, because the planar shape of each recessed portion RP1 of the plurality of reshaped patterns PT1′ is a polygonal shape without a curved line, the recessed portions RP1 can slow the flow of the second encapsulation layer 117b, and the portions between the plurality of reshaped patterns PT1′ (and/or between the recessed portions RP1) may be relatively slowly filled with the second encapsulation layer 117b. Therefore, the plurality of reshaped patterns PT1′ with recessed portions RP1 may be configured to decrease the movement speed of the second encapsulation layer 117b and minimize the flow of the second encapsulation layer 117b. Therefore, even though the plurality of reshaped patterns PT1′ with the recessed portions RP1 is disposed in a smaller area in comparison with the case in which the recessed portions RP1 are absent, a flow of the second encapsulation layer 117b may be minimized. Therefore, in the display device 1200 according to the example embodiment of the present disclosure, the plurality of reshaped patterns PT1′ includes the recessed portions RP1 (e.g., in particular, the plurality of reshaped patterns PT1′ includes the recessed portions RP1 each having a polygonal shape without a curved line), and a flow of the second encapsulation layer 117b is minimized, such that an arrangement area of the plurality of reshaped patterns PT1′ may be minimized. Further, it is possible to implement the display device 1200 with a narrow bezel because a size of a bezel area can be minimized.

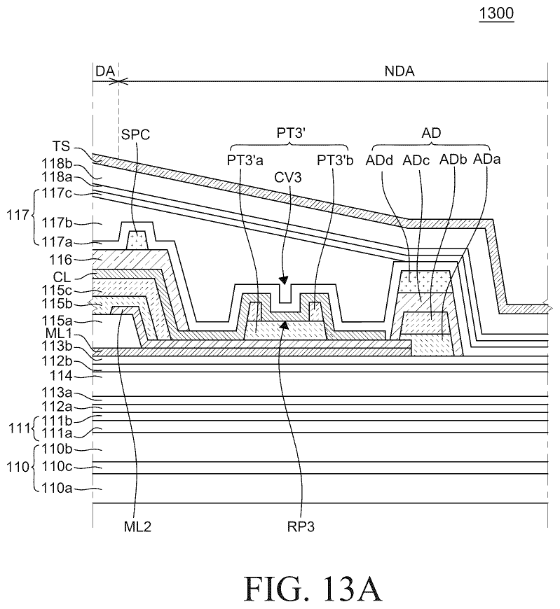

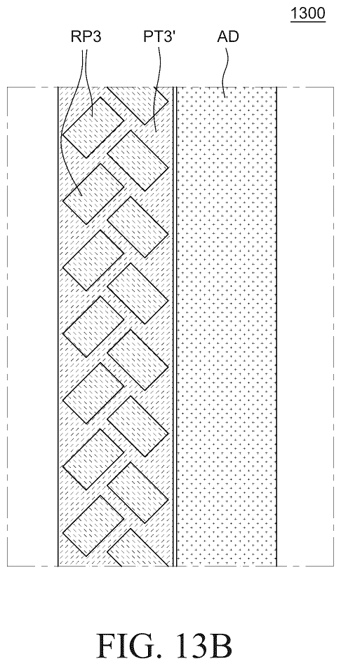

FIG. 13A is another example of a cross-sectional view taken along line B-B's in FIG. 1A. FIG. 13B is an example of a top plan view of a portion of the structure shown in FIG. 13A. For example, FIG. 13B illustrates a reconfigured pattern PT3′ and the outer dam structure AD of FIG. 13A.

A display device 1300 in FIGS. 13A and 13B is, or may be, substantially identical in configuration to the display device in FIGS. 1A to 5 and 6B to 12B (in particular FIGS. 3, 9 and 10), except for a reconfigured pattern PT3′. Therefore, repeated descriptions of the identical or substantially identical components will be omitted. Meanwhile, for the convenience of description, FIG. 13A is substantially identical to FIG. 10, except that the plurality of third patterns PT3 of FIG. 10 is replaced by the reconfigured pattern PT3′ of FIG. 13A. FIG. 13A is substantially identical to FIG. 3, except that the plurality of auxiliary outer dams AAD of FIG. 3 is replaced by the reconfigured pattern PT3′ of FIG. 13A. Further, FIG. 13B is substantially identical to FIG. 9, except that the plurality of third patterns PT3 of FIG. 10 is replaced by the reconfigured pattern PT3′ of FIG. 13A. In one or more other examples, a display device may include one or more reconfigured pattern PT3′, one or more third patterns PT3, one or more auxiliary outer dams AAD, or some combination thereof.

With reference to FIGS. 13A and 13B, the reconfigured pattern PT3′ is disposed inside the outer dam structure AD. The reconfigured pattern PT3′ is disposed between the display area DA and the outer dam structure AD. For example, the reconfigured pattern PT3′ may be disposed along a plurality of imaginary lines disposed to surround the outer dam structure AD. The reconfigured pattern PT3′, together with the outer dam structure AD, may block a flow of the second encapsulation layer 117b. Therefore, for example, the reconfigured pattern PT3′ may be referred to as stoppers. However, the present disclosure is not limited thereto.

Meanwhile, with reference to FIG. 13A, the reconfigured pattern PT3′ may include a first layer PT3′a and a second layer PT3′b. The reconfigured pattern PT3′ may include a plurality of layers formed of the same layers as the second planarization layer 115b and the third planarization layer 115c on which the anode 121 having the side mirror structure is disposed. For example, the first layer PT3′a may be formed of the same layer as the second planarization layer 115b, and the second layer PT3′b may be formed of the same layer as the third planarization layer 115c. However, the reconfigured pattern PT3′ may further include a third layer in addition to the first layer PT3′a and the second layer PT3′b. However, the number of layers included in the reconfigured pattern PT3′ is not limited thereto. In one aspect, a plan view of the reconfigured pattern PT3′ seen at the first and second layers PT3′a and PT3′b is illustrated in FIG. 13B.

The reconfigured pattern PT3′ may include recessed portions RP3. For example, with reference to FIG. 13B, the reconfigured pattern PT3′ is shown with thirteen whole recessed portions (without counting the recessed portions that are depicted partially) disposed along the length direction of the reconfigured pattern PT3′.

With reference to FIGS. 13A and 13B, each recessed portion RP3 may be formed in the second layer PT3′b. For example, the height of each recessed portion RP3 may be identical to the height of the second layer PT3′b. For example, each recessed portion RP3 may be, or may include, an opening in the second layer PT3′b, where the opening begins from the top of the second layer PT3′b and ends at the bottom of the second layer PT3′b.

The connection line (or a first metal line) CL may be disposed on the side surfaces of the first layer PT3′a and the side surfaces and the top surface of the second layer PT3′b. The connection line CL may be also disposed in each recessed portion RP3. For example, the connection line CL may cover the side surfaces of each recessed portion RP3 and a bottom of each recessed portion RP3 (i.e., a top surface of the first layer PT3′a that is exposed by each respective recessed portion RP3).

The first encapsulation layer 117a may be disposed on the outer side surfaces of the connection line CL and the top surface of the connection line CL. The first encapsulation layer 117a may be also disposed in each recessed portion RP3. For example, the first encapsulation layer 117a may cover the inner side surfaces of the connection line CL in each recessed portion RP3 and the lower top surface of the connection line CL in each recessed portion RP3.

The second encapsulation layer 117b may cover the first encapsulation layer 117a. For example, the second encapsulation layer 117b may be disposed on the outer side surfaces of the first encapsulation layer 117a and the top surface of the first encapsulation layer 117a. The second encapsulation layer 117b may be also disposed in (or fill) each recessed portion RP3. For example, the second encapsulation layer 117b may cover the inner side surfaces of the first encapsulation layer 117a in each recessed portion RP3 and the lower top surface of the first encapsulation layer 117a in each recessed portion RP3. In another example, the second encapsulation layer 117b may fill at least a portion of each recessed portion RP3. In yet another example, the second encapsulation layer 117b may fill at least a portion of each of some recessed portions RP3. In yet another example, the second encapsulation layer 117b may fill up to the extended top of each recessed portion RP3 (e.g., fill the entire cavity CV3 created by the first encapsulation layer 117a at each recessed portion RP3), where the extended top is formed by the connection line CL and the first encapsulation layer 117a.

Thus, in one or more examples, the second encapsulation layer 117b may fill at least a portion of a recessed portion RP3, fill at least a portion of each recessed portion RP3, or fill at least a portion of each of some recessed portions RP3. In one or more examples, the second encapsulation layer 117b may fill at least a portion or an entirety of a cavity CV3 at a recessed portion RP3, fill at least a portion or an entirety of a cavity CV3 at each recessed portion RP3, or fill at least a portion or an entirety of a cavity CV3 at each of some recessed portions RP3.

Each recessed portion RP3 formed in the second layer PT3′b may have a polygonal shape in a plan view. A polygonal shape may be, for example, as a quadrangular shape (e.g., a square shape or a rectangle shape) or an octagonal shape.

Meanwhile, the reconfigured pattern PT3′ may include the plurality of layers and thus have a higher height in comparison with a case in which a pattern is disposed as a single layer. Therefore, the reconfigured pattern PT3′ may be configured to more stably control a flow of the second encapsulation layer 117b. In addition, because the area in which the reconfigured pattern PT3′ is disposed may be minimized, a size of the bezel area in the same area may be minimized.

With reference to FIG. 13B, the reconfigured pattern PT3′ may be spaced apart from one another and have the same shape in a plan view. A planar shape of each recessed portion RP3 of the reconfigured pattern PT3′ is a polygonal shape. In this case, because the planar shape of each recessed portion RP3 of the reconfigured pattern PT3′ is a polygonal shape, the reconfigured pattern PT3′ having the recessed portions RP3 may be configured to hinder a flow of the second encapsulation layer 117b disposed above the reconfigured pattern PT3′.

Meanwhile, with reference to FIGS. 1B and 13B, the planar shape of each recessed portion RP3 of the reconfigured pattern PT3′ may be identical to (or may correspond to) a planar shape of s light-emitting area of s green subpixel SPG. For example, the reconfigured pattern PT3′ (or the recessed portions RP3) may be made by using a mask identical to a mask used for the anode 121 for forming an area corresponding to the light-emitting area of the green subpixel SPG during the manufacturing process. Therefore, the number of masks required to dispose the reconfigured pattern PT3′ (or the recessed portions RP3) may be reduced. However, the present disclosure is not limited thereto.

In the display device 1300 according to the example embodiment of the present disclosure, the planar shape of each recessed portion RP3 of the reconfigured pattern PT3′ is a polygonal shape. Because the second encapsulation layer 117b flows into the recessed portions RP3 (and/or the cavities CV3 corresponding to the recessed portions RP3), a flow of the second encapsulation layer 117b (from the display area DA to the non-display area NDA) is minimized, such that an arrangement area of the reconfigured pattern PT3′ may be minimized.

Specifically, because the planar shape of each recessed portion RP3 of the reconfigured pattern PT3′ is a polygonal shape without a curved line, the recessed portions RP3 can slow the flow of the second encapsulation layer 117b, and the portions between the reconfigured pattern PT3′ (and/or between the recessed portions RP3) may be relatively slowly filled with the second encapsulation layer 117b. Therefore, the reconfigured pattern PT3′ with recessed portions RP3 may be configured to decrease the movement speed of the second encapsulation layer 117b and minimize the flow of the second encapsulation layer 117b. Therefore, even though the reconfigured pattern PT3′ with the recessed portions RP3 is disposed in a smaller area in comparison with the case in which the recessed portions RP3 are absent, a flow of the second encapsulation layer 117b may be minimized. Therefore, in the display device 1300 according to the example embodiment of the present disclosure, the reconfigured pattern PT3′ includes the recessed portions RP3 (e.g., in particular, the reconfigured pattern PT3′ includes the recessed portions RP3 each having a polygonal shape without a curved line), and a flow of the second encapsulation layer 117b is minimized, such that an arrangement area of the reconfigured pattern PT3′ may be minimized. Further, it is possible to implement the display device 1300 with a narrow bezel because a size of a bezel area is minimized in the same area.

Various examples and aspects of the present disclosure are described below. These are provided as examples, and do not limit the scope of the present disclosure.

In connection with FIGS. 1A to 5 and 6B to 13B, in one or more aspects, the display device described herein may be, may be included in, or may include, a foldable device. A foldable device may refer to, or may be, a foldable display device, a rollable device, a bendable device, a flexible device, a stretchable device, a curved device, a sliding device, or a variable device, and vice versa. The display device described herein according to one or more aspects of the present disclosure may be, or may be included in, a mobile terminal (e.g., a smart phone, a video phone, a smart watch, a watch phone, a wearable device, a tablet, an electronic notebook, a notebook computer, a netbook computer, an e-book, a portable multimedia player (PMP), a personal digital assistant (PDA), an MPEG-1 Audio Layer 3 (MP3) player, a mobile medical device, a laptop, or the like), a desktop personal computer (PC), a workstation, a navigation device, a car navigation device, a vehicle display device, a vehicle apparatus, a theater apparatus, a theater display device, a television, a wallpaper device, a signage device, a gaming device, a monitor, a camera, a sensor, a camcorder, or a home appliance, or the like. The display device described herein according to one or more aspects of the present disclosure are not limited to the foregoing example devices. The display device described herein according to one or more aspects of the present disclosure may be made in various types, sizes, and shapes that are configured to display information and/or images.

In connection with FIGS. 1A to 5 and 6B to 13B, in one or more aspects, when the display device described herein is a foldable device, a foldable area may be formed around a folding axis. In an example, the foldable area may overlap a portion of the display area DA and/or a portion of the non-display area NDA. The foldable area may be an area that is folded with a predefined curvature when the foldable device is folded in at least one scheme among inner folding and outer folding. An area other than the foldable area may be a non-foldable area. A foldable area may include one or more foldable areas. Moreover, when the display device described herein is the foldable device, the display device may further include a hinge structure for folding a display panel or the like, and a casing for supporting and accommodating the display panel or the like. In one or more examples, when the display device described herein is the foldable device, the substrate of the display device may be a multilayer substrate, and the substrate may be flexible.

In connection with FIGS. 1A to 5 and 6B to 13B, in one or more aspects, the display device described herein may include an optical electronic device. The optical electronic device may be an electronic component that is provided and installed separately from a display panel DP and positioned under the display panel DP (side opposite to the viewing surface). An optical electronic device may include one or more optical electronic devices.

Light may enter the front surface (viewing surface) of the display panel DP and pass through the display panel DP to an optical electronic device positioned under the display panel DP (opposite to the viewing surface). For example, the light passing through the display panel DP may include visible light, infrared light, ultrasonic light, ultraviolet light, and/or the like.

The optical electronic device may be a device that receives the light transmitted through the display panel DP and performs a predetermined function according to the received light. For example, the optical electronic device may include a capture device (e.g., a camera, a camera lens, or an image sensor) and/or a detection sensor (e.g., a proximity sensor and/or an illuminance sensor). For example, the detection sensor may be an infrared sensor. A sensor may be capable of detecting an object or a human body by receiving light.

The display area DA may include an optical area OA. In an example, the optical area OA may overlap an optical electronic device. In an example, the optical area OA may overlap at least a portion or an entirety of an optical electronic device. In an example, at least a portion or an entirety of the optical area OA may overlap an optical electronic device. An optical area OA may include one or more optical areas.

In connection with FIGS. 1A, 5 and 12A, an optical area OA in these examples may have a light transmission structure (e.g., one or more light transmissive areas). In an example, a light transmission structure may include one or more through-holes TH. A through-hole TH, as depicted in FIGS. 5 and 12A, may include some layers (e.g., the substrate 110) and exclude other layers (e.g., the layers above the substrate 110). In these examples, the substrate 110 (or at least the portion of the substrate within the through-hole TH) may be formed of a transparent material(s). In another example (not shown in FIGS. 5 and 12A), a through-hole TH may include the substrate 110 as well as one or more other layers (e.g., one or more dielectric layers including a transparent material(s) and/or one or more metal layers, conductive layers or electrodes including a transparent material(s)).

According to some example embodiments (not shown in FIGS. 5 and 12A), an optical area OA may have both an image display structure (e.g., subpixels including light-emitting elements 120) and a light transmission structure (e.g., one or more light transmissive areas). In other words, since the optical area OA is a partial area of the display area DA, emission areas of subpixels (e.g., emissions areas of the light-emitting elements 120, or first and second light-emitting areas) for displaying images may be disposed in the optical area OA. In an example, a light transmission structure may be used to transmit light to the optical electronic device. In another example, when an optical electronic device is absent, the light transmission structure may be used to transmit light (either toward the back of the display panel or toward the front of the display panel). A light transmissive area may be referred to as a transmissive area, and vice versa. In an example, the image display structure may include a plurality of light-emitting elements 120 (or an array thereof, rows thereof, or columns thereof). In an example, the light transmission structure may include a plurality of light transmissive areas (or an array thereof, rows thereof, or columns thereof). In an example, the light-emitting elements 120 may be disposed between the light transmissive areas. In an example, an array of the light-emitting elements 120 and an array of the light transmissive areas may be interposed. In an example, a light-emitting element 120 may be adjacent to a corresponding light transmissive area. In an example, the light-emitting elements 120 may be disposed between a normal display area NA and one or more light transmissive areas, disposed between a normal display area NA and a dam structure (e.g., ID, AD, AAD), disposed between a normal display area NA and one or more patterns (e.g., PT1, PT2, PT3, PT1′ or PT3′), and/or disposed between one or more patterns (e.g., PT1, PT2, PT3, PT1′ or PT3′) and one or more light transmissive areas.

According to the some example embodiments, a light transmission structure may be configured in one of several different ways. A light transmission structure may be (i) a structure that includes a substrate formed of a transparent material(s); (ii) a structure with one or more dielectric layers formed of a transparent material(s); or (iii) a structure with at least some of the following: one or more dielectric layers as well as one or more metal layers, semiconducting layers, conductive layers, organic layers, and/or electrodes, each of which is formed of a transparent material(s). Therefore, a light transmission structure can be formed of a transparent material(s) that permit light to pass through. A light transmission structure may include one or more light transmission structures. Similarly, according to the some example embodiments, a light transmissive area may be configured in one of several different ways. A light transmissive area may be (i) an area that includes a substrate formed of a transparent material(s); (ii) an area with one or more dielectric layers formed of a transparent material(s); or (iii) an area with at least some of the following: one or more dielectric layers as well as one or more metal layers, semiconducting layers, conductive layers, organic layers, and/or electrodes, each of which is formed of a transparent material(s).

An optical electronic device may be a device that requires light reception, but is positioned behind (below, opposite to the viewing surface) the display panel DP to receive the light transmitted through the display panel DP. In one or more examples, the optical electronic device is not exposed on the front surface (viewing surface) of the display panel DP. Therefore, when the user looks at the front surface of the display device, the optical electronic device is not visible to the user.

When the optical electronic device is a camera, the camera may be a front camera that is positioned behind (below) the display panel DP but captures forward of the display panel DP. Accordingly, the user may take a photograph through the camera invisible to the viewing surface while viewing the viewing surface of the display panel DP.

According to the some example embodiments, the normal display area NA and the optical area OA included in the display area DA are areas that may display images, but the normal display area NA is an area that does not require a light transmission structure to be formed, and the optical area OA may be an area that includes a light transmission structure.

According to the some example embodiments, the optical area OA may have a transmittance (e.g., a transmittance per unit area) higher than or equal to a certain level, and the normal display area NA may have no light transmittance or a lower transmittance (e.g., a lower transmittance per unit area) that is less than the certain level.

According to the some example embodiments, the optical area OA (or an image display structure therein) may include some of the elements shown in FIG. 2 (e.g., the light-emitting element, some or all of the insulating layers, and/or some of the other elements). However, the optical area OA and the normal display area NA according to the some example embodiments may have different resolutions, subpixel placement structures, numbers of subpixels per unit area, electrode structures, line structures, electrode placement structures, and/or line placement structures.

For example, the number of subpixels per unit area in an optical area OA may be different from the number of subpixels per unit area in the normal display area NA, or the size of each subpixel (i.e., the size of the emission area) disposed in the optical area OA may be different from the size of a corresponding subpixel (i.e., the size of the emission area) disposed in the normal display area NA. In another example, the number of subpixels per unit area in an optical area OA may be the same as the number of subpixels per unit area in the normal display area NA, or the size of each subpixel (i.e., the size of the emission area) disposed in the optical area OA may be the same as the size of a corresponding subpixel (i.e., the size of the emission area) disposed in the normal display area NA.

In an example, the number of subpixels per unit area in an optical area OA may be smaller than the number of subpixels per unit area in the normal display area NA. In other words, the resolution of an optical area OA may be lower than the resolution of the normal display area NA. Here, the number of subpixels per unit area may be equivalent to resolution, or pixel density, or pixel integration degree. For example, the unit for the number of subpixels per unit area may be pixels per inch (PPI), which represents the number of pixels in one inch. In the foregoing example, the size of each subpixel (i.e., the size of the emission area) disposed in the optical area OA may be the same as the size of a corresponding subpixel (i.e., the size of the emission area) disposed in the normal display area NA.

In another example, the size of each subpixel (i.e., the size of the emission area) disposed in the optical area OA may be larger than the size of a corresponding subpixel (i.e., the size of the emission area) disposed in the normal display area NA.

In yet another example, the number of subpixels per unit area of the optical area OA may be larger than the number of subpixels per unit area of the normal display area NA.

In yet another example, the number of subpixels (or emission areas) per unit area of the optical area OA is identical or similar to the number of subpixels (or emission areas) per unit area of the normal display area NA, and the size of each subpixel (i.e., the size of the emission area) disposed in the optical area OA is smaller than the size of a corresponding subpixel (i.e., the size of the emission area) disposed in the normal display area NA.

An optical area OA may have various shapes, such as a circle, an ellipse, a quadrangle, a hexagon, or an octagon. Furthermore, an image display structure and a light transmission structure within the optical area OA may have various shapes.

In the display device according to the some example embodiments, if the optical electronic device that is not exposed to the outside and is hidden in a lower portion of the display panel DP is a camera, the display device according to the some example embodiments may be referred to as a display to which under display camera (UDC) technology has been utilized.

According to the some example embodiments, the display device does not require a notch or a camera hole for camera exposure to be formed in the display panel DP, thereby preventing a reduction in the display area DA. Thus, as there is no need to form a notch or a camera hole for exposure of the camera in the display panel DP, the size of the bezel area may be reduced, and design restrictions may be freed, thereby increasing the degree of freedom in design. In an example, a notch or a camera hole may be a hollow space or a void lacking solid materials, metals or dielectric layers.

According to the some example embodiments, although an optical electronic device is positioned to be hidden behind the display panel DP, the optical electronic device can function as intended, such as receiving light properly and performing its predetermined functions in a normal manner.

Further, according to the some example embodiments, although an optical electronic device is positioned to be hidden behind the display panel DP and is positioned to overlap the display area DA, the optical area OA overlapping the optical electronic device in the display area DA can display images. However, when the optical area OA is designed as a transmissive area (or a transmittable area), the image display characteristics in the optical area OA may differ from the image display characteristics in the normal display area NA.

According to the some example embodiments, the normal display area NA and the optical area OA (and the components therein) described herein may be utilized and implemented in the display device illustrated with reference to FIGS. 1A to 5 and 6B to 13B.

The light transmission structure described above according to the some example embodiments does not require a notch or a camera hole. However, in another example, a light transmissions structure may include a notch or a camera hole.

Various examples and aspects of the present disclosure are described further below. These are provided as examples, and do not limit the scope of the present disclosure.

In one or more aspects, the phrase, “a polygonal shape without a curved line” or the phrase, “a polygonal shape” may represent a polygonal shape without an intended curved line (or without an intended rounded corner). During the manufacturing process of a display device, an unintended curved line may be created in a polygonal shape (e.g., a polygonal shape of a recessed portion RP1 or RP3 of FIG. 12A or FIG. 13A, or a polygonal shape of the light-emitting area of the green subpixel SPG of FIG. 1B) while the polygonal shape is being formed. For example, such unintended curved line may result from an etching process or a deposition process. Thus, a polygonal shape without a curved line, or a polygonal shape, may have an unintended curved line. In some aspects, an unintended curved line may be an inherent feature of a display device manufacturing process.

In one or more examples, color filters (not shown in the figures) may be disposed on the encapsulation layer 117. Each color filter may overlap a light-emitting area of a subpixel.

In an example, a light-emitting area may be, or may include, a first light-emitting area. In another example, a light-emitting area may include a second light-emitting area. In yet another example, a light-emitting area may be, or may include, both the first and second light-emitting areas.

In one or more examples, a first metal layer may refer to a connection line CL. In one or more examples, a transparent material may be, or may include, a light-transmissive material. In some examples, a transparent material may include, or may be, a semi-transparent material.

In one or more examples, the display area DA may include one or more optical areas OA. In one or more examples, an optical area OA may include one or more optical areas OA. In one or more examples, an optical area OA may include a plurality of through-holes TH.

In one or more examples, a plurality of patterns may include a plurality of first patterns. In one or more examples, a plurality of patterns may include a plurality of second patterns. In one or more examples, a plurality of patterns may include a plurality of third patterns.

In one or more examples, a dam structure may include an outer dam structure. In some examples, a dam structure may include a plurality of auxiliary outer dams AAD. In one or more examples, a dam structure may include an inner dam structure.

In one or more examples, one or more planarization layers may include a second planarization layer and/or a third planarization layer. In some examples, the second planarization layer and the third planarization layer are formed separately as separate layers. In some examples, the second planarization layer and the third planarization layer are formed together as a single layer.

In one or more examples, an anode 121 may be disposed on a lower top surface of the one or more planarization layers. In some examples, the lower top surface of the one or more planarization layers may correspond to an area that includes a first light-emitting area. The first light-emitting area may correspond to an area in which the top surface of the anode 121 is exposed by the bank 116, as illustrated in FIG. 2. In some examples, the first light-emitting area may be surrounded (or enclosed) by a first non-light-emitting area, which may be surrounded (or enclosed) by a second light-emitting area, which may be surrounded (or enclosed) by a second non-light-emitting area.

In one or more examples, an anode 121 may be disposed on a part of an upper top surface of the one or more planarization layers. In some examples, a part of the upper top surface of the one or more planarization layers may correspond to an area that includes the second non-light-emitting area in which the anode 121 is disposed on the flat top surface of the third planarization layer 115c, as illustrated in FIG. 2.

In one or more examples, one or more dam layers may include a first layer ADa and a second layer ADb. In one or more examples, one or more dam layers may include a first layer IDa and a second layer IDb. In some examples, a second dam layer may include a third layer ADc, a third dam layer may include a fourth layer ADd, and a fourth dam layer may include a fifth layer formed of the same layer as the first planarization layer 115a.

In one or more examples, one or more auxiliary dams may include one or more auxiliary outer dams AAD or a plurality of auxiliary outer dams AAD.

In one or more examples, a plurality of patterns disposed adjacent to and along the dam structure may include a plurality of third patterns PT3. In one or more examples, a plurality of patterns disposed adjacent to and along the dam structure may include a plurality of first patterns PT1. In one or more examples, each of the plurality of patterns may form a discrete island, such as each island of PT1 and PT3.

In one or more examples, each of the plurality of patterns may include one or more pattern layers, such as PT3a/PT3b of FIG. 10, or PT1a/PT1b of FIG. 5.

In one or more examples, a light-emitting layer 122 may be disposed on the one or more pattern layers and an area adjacent to the one or more pattern layers, as illustrated in FIG. 5. In one or more examples, the light-emitting layer 122 on the one or more pattern layers may be disconnected from the light-emitting layer 122 on the area adjacent to the one or more pattern layers by a undercut structure.

In one or more examples, a first metal layer CL may be disposed on the one or more pattern layers as illustrated in FIG. 10, and the first metal layer CL may be formed of a same layer as the anode 121 without being electrically connected to the anode 121.

In one or more examples, one or more metal layers ML1/ML2 may be disposed below the one or more pattern layers as illustrated in FIG. 10, and the first metal layer CL may be connected to the one or more metal layers ML1/ML2 and a cathode 123.

In one or more examples, a display device 1200 or 1300 of FIGS. 12A to 12C or FIGS. 13A and 13B may include: a substrate 110; a display area DA in which a plurality of subpixels is disposed; a non-display area NDA; one or more planarization layers 115b/115c disposed on the substrate; an anode 121 disposed on a surface of the one or more planarization layers, wherein the surface corresponds to an area including a first light-emitting area, and wherein the surface faces away from the substrate; an encapsulation layer 117/117b disposed on the one or more planarization layers; and a pattern PT1′ or PT3′ disposed on the substrate and comprising one or more pattern layers PT1′a/PT1′b or PT3′a/PT3′b formed of one or more same layers as the one or more planarization layers. The pattern may have recessed portions RP1 or RP3. At least portions of the encapsulation layer may be provided in the recessed portions.

In one or more examples, the pattern PT1′ or PT3′ may be disposed in an optical area OA of the display area DA or disposed in the non-display area NDA.

In one or more examples, each of the recessed portions RP1 or RP3 may have a polygonal shape in a plan view, and the recessed portions may be separate and distinct from one another.

In one or more examples, the plurality of subpixels may comprise a red subpixel, a green subpixel, and a blue subpixel; and a planar shape of each of the recessed portions may be identical to a planar shape of a light-emitting area of the green subpixel SPG.

In one or more examples, the pattern PT1′ or PT3′ may comprise a raised structure in a cross-sectional view, and the recessed portions RP1 or RP3 may be provided within the raised structure.

In one or more examples, the pattern PT1′ or PT3′ may have a length and a width, where the length is longer than the width, and the recessed portions RP1 or RP3 are provided along the length.

In one or more examples, the one or more pattern layers PT1′a/PT1′b or PT3′a/PT3′b of FIG. 12A or 13A may include a first pattern layer PT1′a or PT3′a disposed on the substrate and a second pattern layer PT1′b or PT3′b disposed on the first pattern layer; and the recessed portions RP1 or RP3 may comprise openings in the second pattern layer.

In one or more examples, a light-emitting layer 122 of FIG. 12A or 12B may be provided in the recessed portions RP1, and in the recessed portions RP1, the at least portions of the encapsulation layer 117/117b may be provided on the light-emitting layer.

In one or more examples, a first metal layer CL of FIG. 13A may be provided on the one or more pattern layers PT3′a/PT3′b and in the recessed portions RP3. The first metal layer may be formed of a same layer as the anode without being electrically connected to the anode 121. One or more metal layers ML1/ML2 may be disposed below the one or more pattern layers. The first metal layer may be connected to the one or more metal layers. The first metal layer may be also connected to a cathode 123.

In one or more examples, the display device 1200 or 1300 may further include a dam structure ID or AD disposed on the substrate and comprising one or more dam layers IDa/IDb or Ada/ADb formed of one or more same layers as the one or more planarization layers 115b/115c, wherein the pattern PT1′ or PT3′ may be disposed along the dam structure.

Various examples and aspects of the present disclosure are further described below. These are provided as examples, and do not limit the scope of the present disclosure.

A display device according to one or more example embodiments of the present disclosure may include: a substrate; a display area in which a plurality of subpixels is disposed; an optical area; a non-display area outside the display area; a transistor disposed in each of the plurality of subpixels on the substrate; a first planarization layer disposed on the transistor; a second planarization layer disposed on the first planarization layer; a third planarization layer disposed on the second planarization layer and configured to expose parts of a top surface of the second planarization layer; an anode disposed in each of the plurality of subpixels and configured to cover a part of the top surface of the second planarization layer and a part of the third planarization layer; a dam structure disposed on the substrate and including a first layer formed of a same layer as the second planarization layer, and a second layer formed of a same layer as the third planarization layer; and a plurality of first patterns disposed along the dam structure, wherein each of the plurality of first patterns has a planar shape including a curved line.

The planar shape of each of the plurality of first patterns may be any one of a rectangular shape with rounded corners, a circular shape, and an elliptical shape.

The display device may further comprise a second pattern disposed between the plurality of first patterns and the dam structure and configured to surround a through-hole of the optical area.

The plurality of subpixels may comprise a red subpixel, a green subpixel, and a blue subpixel.

The plurality of first patterns may each comprise a first layer formed of a same layer as the second planarization layer, and a second layer formed of a same layer as the third planarization layer.

A first metal layer may be disposed on the second layer. The first metal layer may be formed of a same layer as the anode without being electrically connected to the anode.

The display device may further comprise a bank disposed to cover a part of the third planarization layer and a part of the anode.

The dam structure may further comprise a third layer formed of a same layer as the bank.

A display device according to one or more example embodiments of the present disclosure may include: a substrate; a display area; a non-display area configured to surround the display area; a first planarization layer disposed on the substrate; a second planarization layer disposed on the first planarization layer; a third planarization layer disposed on the second planarization layer and configured to expose a top surface of the second planarization layer; an anode disposed to cover a part of the second planarization layer and a part of the third planarization layer; a dam structure disposed in the non-display area on the substrate while surrounding the display area and including a first layer formed of a same layer as the second planarization layer, and a second layer formed of a same layer as the third planarization layer; and a plurality of patterns disposed between the dam structure and the display area along the dam structure, wherein each of the plurality of patterns has having a planar shape including a curved line.

The planar shape each of the plurality of patterns may be any one of a rectangular shape with rounded corners, a circular shape, and an elliptical shape.

The display device may further comprise a plurality of subpixels disposed in the display area and comprising a red subpixel, a green subpixel, and a blue subpixel.

The plurality of patterns may each comprise a first layer formed of a same layer as the second planarization layer, and a second layer formed of a same layer as the third planarization layer.

The display device may further comprise a bank disposed on the third planarization layer and configured to expose a part of the anode.

The dam structure may further comprise a third layer formed of a same layer as the bank.

A display device according to one or more example embodiments of the present disclosure may include: a substrate; a display area; a non-display area; one or more planarization layers disposed on the substrate, wherein the one or more planarization layers comprise a lower top surface and an upper top surface; an anode disposed on the lower top surface and a part of the upper top surface of the one or more planarization layers, wherein the lower top surface corresponds to an area including a first light-emitting area, and wherein each of the lower top surface and the upper top surface faces away from the substrate; and a dam structure disposed on the substrate and comprising one or more dam layers formed of one or more same layers as the one or more planarization layers.

The dam structure may surround the display area or a through-hole of an optical area.

The display device may comprise: a plurality of patterns disposed adjacent to and along the dam structure, wherein: each of the plurality of patterns forms a discrete island; and each of the plurality of patterns has a planar shape including one or more curved portions.

Each of the plurality of patterns may comprise: one or more pattern layers formed of one or more same layers as the one or more planarization layers.

The dam structure may further comprise: a second dam layer disposed on the one or more dam layers and formed of a same layer as a bank in the display area; and a third dam layer disposed on the second dam layer and formed of a same layer as a spacer in the non-display area.

The dam structure may further comprise: a fourth dam layer disposed below the one or more dam layers and formed of a layer same as a first planarization layer disposed below the one or more planarization layers.

The display device may further comprise: one or more auxiliary dams disposed between the display area and the dam structure, wherein each of the one or more auxiliary dams is formed of a same layer as one of the one or more planarization layers.

The display device may have a configuration, wherein: a light-emitting layer is disposed on the one or more pattern layers and an area adjacent to the one or more pattern layers; an undercut structure is disposed below the one or more pattern layers; and the light-emitting layer on the one or more pattern layers is disconnected, from the light-emitting layer on the area adjacent to the one or more pattern layers, by the undercut structure.

A first metal layer may be disposed on the one or more pattern layers, wherein the first metal layer is formed of a same layer as the anode without being electrically connected to the anode. One or more metal layers may be disposed below the one or more pattern layers. The first metal layer may be connected to the one or more metal layers and a cathode.

The display device may have a configuration, wherein: the first light-emitting area is enclosed by a first non-light-emitting area; the first non-light-emitting area is enclosed by a second light-emitting area; and the second light-emitting area is enclosed by a second non-light-emitting area.

The display device may have a configuration, wherein: the first light-emitting area corresponds to an area in which a top surface of the anode is exposed by a bank; the first non-light-emitting area corresponds to an area in which the anode disposed on the lower top surface of the one or more planarization layers is covered by the bank; the second light-emitting area corresponds to an area in which a part of light emitted from a light-emitting layer is for being reflected by the anode disposed on an inclined surface of an upper portion of the one or more planarization layers; and the second non-light-emitting area corresponds to an area in which the anode is disposed on the part of the upper top surface of the one or more planarization layers, wherein the part of the upper top surface is flat.

A display device according to one or more example embodiments of the present disclosure may include: a substrate; a display area in which a plurality of subpixels is disposed; a non-display area; one or more planarization layers disposed on the substrate; an anode disposed on a surface of the one or more planarization layers, wherein the surface corresponds to an area including a first light-emitting area, and wherein the surface faces away from the substrate; an encapsulation layer disposed on the one or more planarization layers; and a pattern disposed on the substrate and comprising one or more pattern layers formed of one or more same layers as the one or more planarization layers, wherein: the pattern has recessed portions; and at least portions of the encapsulation layer are provided in the recessed portions.

The pattern may be disposed in an optical area of the display area or disposed in the non-display area.

The display device may have a configuration, wherein: each of the recessed portions has a polygonal shape in a plan view; and the recessed portions are separate and distinct from one another.

The display device may have a configuration, wherein: the plurality of subpixels comprises a red subpixel, a green subpixel, and a blue subpixel; and a planar shape of each of the recessed portions is identical to a planar shape of a light-emitting area of the green subpixel.

The display device may have a configuration, wherein: the pattern comprises a raised structure in a cross-sectional view; and the recessed portions are provided within the raised structure.

The display device may have a configuration, wherein: the pattern has a length and a width; the length is longer than the width; and the recessed portions are provided along the length.

The display device may have a configuration, wherein: the one or more pattern layers include a first pattern layer disposed on the substrate and a second pattern layer disposed on the first pattern layer; and the recessed portions comprise openings in the second pattern layer.

The display device may have a configuration, wherein: a light-emitting layer is provided in the recessed portions; and in the recessed portions, the at least portions of the encapsulation layer are provided on the light-emitting layer.

The display device may have a configuration, wherein: a first metal layer may be provided on the one or more pattern layers and in the recessed portions, wherein the first metal layer is formed of a same layer as the anode without being electrically connected to the anode; one or more metal layers are disposed below the one or more pattern layers; and the first metal layer is connected to the one or more metal layers.

The display device may further include a dam structure disposed on the substrate and comprising one or more dam layers formed of one or more same layers as the one or more planarization layers, wherein the pattern is disposed along the dam structure.

Although the example embodiments of the present disclosure have been described in detail with reference to the accompanying drawings, the present disclosure is not limited thereto and may be embodied in many different forms without departing from the technical concepts of the present disclosure. Therefore, the example embodiments of the present disclosure are provided for illustrative purposes only but not intended to limit the technical concepts of the present disclosure. The scope of the technical concepts of the present disclosure is not limited thereto. Therefore, it should be understood that the above-described example embodiments are illustrative in all aspects and do not limit the present disclosure. The protective scope of the present disclosure should be construed based on the following claims, and all the technical concepts in the equivalent scope thereof should be construed as falling within the scope of the present disclosure.

What is claimed is:

1. A display device, comprising:
a substrate;
a display area in which a plurality of subpixels is disposed;
an optical area;
a non-display area outside the display area;
a transistor disposed in each of the plurality of subpixels on the substrate;
a first planarization layer disposed on the transistor;
a second planarization layer disposed on the first planarization layer;
a third planarization layer disposed on the second planarization layer and configured to expose parts of a top surface of the second planarization layer;
an anode disposed in each of the plurality of subpixels and configured to cover a part of the top surface of the second planarization layer and a part of the third planarization layer;
a dam structure disposed on the substrate and comprising a first layer formed of a same layer as the second planarization layer, and a second layer formed of a same layer as the third planarization layer; and
a plurality of first patterns disposed along the dam structure, wherein each of the plurality of first patterns has a planar shape including a curved line.

2. The display device of claim 1, wherein the planar shape of each of the plurality of first patterns is any one of a rectangular shape with rounded corners, a circular shape, and an elliptical shape.

3. The display device of claim 1, further comprising:
a second pattern disposed between the plurality of first patterns and the dam structure and configured to surround a through-hole in the optical area.

4. The display device of claim 1, wherein each of the plurality of first patterns comprises:
a first layer formed of a same layer as the second planarization layer; and
a second layer formed of a same layer as the third planarization layer.

5. The display device of claim 1, further comprising:
a bank disposed to cover a part of the third planarization layer and a part of the anode,
wherein the dam structure further comprises a third layer formed of a same layer as the bank.

6. A display device, comprising:
a substrate;
a display area;
a non-display area configured to surround the display area;
a first planarization layer disposed on the substrate;
a second planarization layer disposed on the first planarization layer;
a third planarization layer disposed on the second planarization layer and configured to expose a top surface of the second planarization layer;
an anode disposed to cover a part of the second planarization layer and a part of the third planarization layer;
a dam structure disposed in the non-display area on the substrate while surrounding the display area and comprising a first layer formed of a same layer as the second planarization layer, and a second layer formed of a same layer as the third planarization layer; and
a plurality of patterns disposed between the dam structure and the display area along the dam structure, wherein each of the plurality of patterns has a planar shape including a curved line.

7. The display device of claim 6, wherein the planar shape of each of the plurality of patterns is any one of a rectangular shape with rounded corners, a circular shape, and an elliptical shape.

8. The display device of claim 6, wherein each of the plurality of patterns comprises:
a first layer formed of a same layer as the second planarization layer; and
a second layer formed of a same layer as the third planarization layer.

9. The display device of claim 8, wherein:
a first metal layer is disposed on the second layer, wherein the first metal layer is formed of a same layer as the anode without being electrically connected to the anode.

10. The display device of claim 6, further comprising:
a bank disposed on the third planarization layer and configured to expose a part of the anode,
wherein the dam structure further comprises a third layer formed of a same layer as the bank.

11. A display device, comprising:
a substrate;
a display area;
a non-display area;
one or more planarization layers disposed on the substrate, wherein the one or more planarization layers comprise a lower top surface and an upper top surface;
an anode disposed on the lower top surface and a part of the upper top surface of the one or more planarization layers, wherein the lower top surface corresponds to an area including a first light-emitting area, and wherein each of the lower top surface and the upper top surface faces away from the substrate; and
a dam structure disposed on the substrate and comprising one or more dam layers formed of one or more same layers as the one or more planarization layers.

12. The display device of claim 11, wherein the dam structure surrounds the display area or a through-hole of an optical area.

13. The display device of claim 11, comprising:
a plurality of patterns disposed adjacent to and along the dam structure,
wherein:
each of the plurality of patterns forms a discrete island; and
each of the plurality of patterns has a planar shape including one or more curved portions.

14. The display device of claim 13, wherein each of the plurality of patterns comprises:
one or more pattern layers formed of one or more same layers as the one or more planarization layers.

15. The display device of claim 11, wherein the dam structure further comprises:
a second dam layer disposed on the one or more dam layers and formed of a same layer as a bank in the display area; and
a third dam layer disposed on the second dam layer and formed of a same layer as a spacer in the non-display area.

16. The display device of claim 15, wherein the dam structure further comprises:
a fourth dam layer disposed below the one or more dam layers and formed of a layer same as a first planarization layer disposed below the one or more planarization layers.

17. The display device of claim 11, further comprising:
one or more auxiliary dams disposed between the display area and the dam structure,
wherein each of the one or more auxiliary dams is formed of a same layer as one of the one or more planarization layers.

18. The display device of claim 14, wherein:
a light-emitting layer is disposed on the one or more pattern layers and an area adjacent to the one or more pattern layers;
an undercut structure is disposed below the one or more pattern layers; and
the light-emitting layer on the one or more pattern layers is disconnected, from the light-emitting layer on the area adjacent to the one or more pattern layers, by the undercut structure.

19. The display device of claim 14, wherein:
a first metal layer is disposed on the one or more pattern layers, wherein the first metal layer is formed of a same layer as the anode without being electrically connected to the anode;
one or more metal layers are disposed below the one or more pattern layers; and
the first metal layer is connected to the one or more metal layers and a cathode.

20. The display device of claim 14, wherein:
the first light-emitting area is enclosed by a first non-light-emitting area;
the first non-light-emitting area is enclosed by a second light-emitting area; and
the second light-emitting area is enclosed by a second non-light-emitting area.

21. The display device of claim 20, wherein:
the first light-emitting area corresponds to an area in which a top surface of the anode is exposed by a bank;
the first non-light-emitting area corresponds to an area in which the anode disposed on the lower top surface of the one or more planarization layers is covered by the bank;
the second light-emitting area corresponds to an area in which a part of light emitted from a light-emitting layer is for being reflected by the anode disposed on an inclined surface of an upper portion of the one or more planarization layers; and
the second non-light-emitting area corresponds to an area in which the anode is disposed on the part of the upper top surface of the one or more planarization layers, wherein the part of the upper top surface is flat.

22. A display device, comprising:
a substrate;
a display area in which a plurality of subpixels is disposed;
a non-display area;
one or more planarization layers disposed on the substrate;
an anode disposed on a surface of the one or more planarization layers, wherein the surface corresponds to an area including a first light-emitting area, and wherein the surface faces away from the substrate;
an encapsulation layer disposed on the one or more planarization layers; and
a pattern disposed on the substrate and comprising one or more pattern layers formed of one or more same layers as the one or more planarization layers,
wherein:
the pattern has recessed portions; and
at least portions of the encapsulation layer are provided in the recessed portions.

23. The display device of claim 22, wherein the pattern is disposed in an optical area of the display area or disposed in the non-display area.

24. The display device of claim 22, wherein:
each of the recessed portions has a polygonal shape in a plan view; and
the recessed portions are separate and distinct from one another.

25. The display device of claim 22, wherein:
the plurality of subpixels comprises a red subpixel, a green subpixel, and a blue subpixel; and
a planar shape of each of the recessed portions is identical to a planar shape of a light-emitting area of the green subpixel.

26. The display device of claim 22, wherein:
the pattern comprises a raised structure in a cross-sectional view; and
the recessed portions are provided within the raised structure.

27. The display device of claim 22, wherein:
the pattern has a length and a width;
the length is longer than the width; and
the recessed portions are provided along the length.

28. The display device of claim 22, wherein:
the one or more pattern layers include a first pattern layer disposed on the substrate and a second pattern layer disposed on the first pattern layer; and
the recessed portions comprise openings in the second pattern layer.

29. The display device of claim 22, wherein:
a light-emitting layer is provided in the recessed portions; and
in the recessed portions, the at least portions of the encapsulation layer are provided on the light-emitting layer.

30. The display device of claim 22, wherein:
a first metal layer is provided on the one or more pattern layers and in the recessed portions, wherein the first metal layer is formed of a same layer as the anode without being electrically connected to the anode;
one or more metal layers are disposed below the one or more pattern layers; and
the first metal layer is connected to the one or more metal layers.

31. The display device of claim 22, further comprising:
a dam structure disposed on the substrate and comprising one or more dam layers formed of one or more same layers as the one or more planarization layers,
wherein the pattern is disposed along the dam structure.
